(19) United States
(12) Patent Application Publication
(10) Pub. No.: US 2022/0204766 A1
(43) Pub. Date: Jun. 30, 2022

(54) HIGH MOLECULAR WEIGHT FLEXIBLE CURABLE POLYIMIDES

(71) Applicant: Designer Molecules, Inc., San Diego, CA (US)

(72) Inventors: Farhad G Mizori, San Diego, CA (US); Eunsook Chae Barber, San Diego, CA (US)

(21) Appl. No.: 17/604,988

(22) PCT Filed: Apr. 17, 2020
(86) PCT No.: PCT/US2020/028871

§ 371 Date: Oct. 19, 2021

Related U.S. Application Data
(60) Provisional application No. 62/836,582, filed on Apr. 19, 2019.

(51) Int. Cl. C08L 79/08; C08J 5/24; C08G 73/12; H05K 3/02; H05K 1/03

(52) U.S. Cl. CPC C08L 79/085; C08J 5/24; C08G 73/122; H05K 3/022; H05K 2201/0154; H05K 1/0393; H05K 1/0366; C08L 2203/16; H05K 1/0346

(57) ABSTRACT

Curable polyimides with very good dielectric properties have been prepared. These materials also are ideal for being transformed into flexible films that are ready to be laminated for example between copper foils for applications such as copper clad laminates.

### RELATED APPLICATIONS

This application claims the benefit of priority under 35 USC § 119 of U.S. Provisional Patent Application Ser. No. 62/836,582 (filed Apr. 19, 2019), the entire disclosure of which is incorporated herein by reference.

### FIELD OF INVENTION

The invention disclosed herein relates to curable polyimides resins with low dielectric constants and low dielectric dissipation factors. In particular, the invention is directed to high molecular weight, flexible polyimide resins that are terminated with curable moieties. In certain aspects, the invention is directed toward curable polyimide resins with average molecular weights greater than 20,000 Daltons, which form flexible, rollable films when dried, and upon heating and curing form flexible thermoset adhesives that can be used as adhesive dielectric layers in copper clad laminates.

### BACKGROUND OF INVENTION

Due to the rapid increase in the communication of information, there is a strong demand for miniaturization, weight reduction and increased speed of electronic devices for high-density mounting in smart phones, tablets, laptops, WiFi routers and the like. The electronics industry has increasingly demanded low dielectric, electrically insulating materials and polymers that are adapted for operation in high-power, high-frequency environments.

The polymeric materials used in high-power devices must satisfy critical thermal, environmental, and electrical requirements to meet performance criteria for use in high-power microelectronics devices, including high temperature thermal stability, low moisture uptake, high breakdown voltage (low leakage current), low dielectric constant and low dissipation factor. Use of polymers fulfilling these criteria facilitates high performance electronic packaging that is needed to achieve efficient high-power operation, resulting in improved system performance and reliability.

To ensure proper operation of high-power electronic circuits, isolation must be provided between adjacent conductors, which is typically provided by a dielectric material. High-voltage arcing and leakage currents are problems typically encountered in high-voltage circuits, which are exacerbated at high frequencies. To counter these problems, dielectric materials must have low values for dielectric constant and dissipation factor (loss tangent) and a high value for breakdown voltage. As demands of the electronics industry increase, the demand for polymer dielectrics also increases. Thus, there is a continuing need for improved polymers to support the increasingly stringent needs of the electronics industry.

Polyimides are frequently used as dielectrics in electronics. Among polyimides, maleimide-functionalized compounds, including bismaleimides (BMI resins), are top-tier, high performance resins. These compounds have been used extensively in electronics, aerospace and other industries that require high temperature reliability.

### Polyimide Synthesis

The classic synthesis of polyimides is carried out in two-step process of adding one equivalent of a dianhydride to a solution of one equivalent of a diamine, in a polar aprotic solvent such as 1-Methyl-2-pyrrolidone (NMP); Dimethylformamide (DMF); Dimethyl sulfoxide (DMSO); and Dimethylacetamide (DMAC), which forms a polyamic acid. This step is followed by conversion of the polyamic acid to a polyimide via ring closure at, e.g., elevated temperature.

U.S. Pat. No. 3,179,630 B2 discloses a classic polyimide synthesis procedure, in which the starting materials as well as well as the polyamic acid intermediate were highly soluble in the same solvent. The reaction produced high molecular weight polyamic acid when the highly exothermic reaction was conducted at or below room temperature over 12-48 hours.

For very high glass transition temperature (T_{g}), infusible, intractable aromatic polyimides were thermally converted to thin films. The polyamic acid solution was doctor-bladed into a thin film, followed by repeated heating and drying steps. Initially, a lower temperature heating step at about 100° C. was used to remove and replace the solvent, followed by high-temperature heating at 200-300° C. to complete a cyclodehydration reaction and form the polyimide film. Typically, the higher the temperature used, the greater the degree of imidization achieved. However, the high temperatures required to obtain a high degree of imidization can be problematic as certain polyimides are unstable at elevated temperatures and functionalizations can prematurely cure at such temperatures. Furthermore, incomplete ring closure can lead to undesirable moisture absorption with polyimides produced using this method.

The solution of polyamic acid was converted to the polyimide with a chemical imidization agent (i.e. acetic anhydride) in the presence of a tertiary amine basic catalyst (i.e., and amine with a base such as a tertiary amine.

U.S. Pat. No. 9,617,386 B2 discloses the synthesis of polyimides by reacting 2,2′-bis(3,4-dicarboxyphenyl)hexafluoropropane dianhydride (6-FDA) with an excess of 4,4′-[1,4-phenylene-bis(1-methylethylidene)]bianiline (DAPI) in NMP, followed by heating the solution at 60° C. for 3 hours to form the polyamic acid. The amine termini were then reacted with 7-oxabicyclo[2.2.1]hept-5-ene-2,3-dicarboxylic anhydride. Subsequently, an excess of acetic anhydride and pyridine was added to the solution, followed by heating at 100° C. for 12 hours to form the polyimide. The solution was purified dilution with ethyl acetate/acetone, followed by several washes with dilute aqueous hydrochloric acid and distilled water to purify the polyimide product. Polyimides that were synthesized by this method were soluble in acetone and ethyl acetate, which limits the application of this method to other polyimides. The washes that were used to remove the imidization agents and solvent were time consuming and wasteful of hazardous solvents. Although the authors were able to remove the NMP solvent from the synthesis product, chemical imidization with acetic anhydride and pyridine produces incomplete conversion to the polyimide. (See e.g., U.S. Pat. No. 3,179,633). Moreover, polyimides produced using chemical imidization can also absorb moisture due to incomplete closure of polyimide rings, as described above.

U.S. Pat. No. 5,789,524 discloses methods and reactions for synthesizing polyimides by reacting a polyamic acid (synthesized by reacting a diamine with a tetracarboxylic acid dianhydride in an organic solvent) and/or a polyamic ester, with a chemical imidization reagent (phosphoramide) along with a base catalyst (e.g., triethylamine). It is unclear whether this method produced a more complete imidization than other chemical imidization reactions because the inventors reported only Fourier-transform infrared (FTIR) spectra rather than more definitive nuclear magnetic resonance (NMR) as evidence of polyimide formation.

The common shortcoming of methods reported in the art is confirmed or suspected incomplete imidization using either the traditional two-step heating process or chemical imidization. Incomplete imidization can cause added moisture absorption, which is not desirable in electronics application. Furthermore, incomplete imidization can lead to higher Dk and Df. In electronics applications, these properties can lead to poor performance, disappointing dielectric properties and voiding due to moisture in the polymer matrix.

### Maleimide-Terminated Polyimides

U.S. Pat. Nos. 7,884,174 and 7,157,587 (which are incorporated by reference herein in their entirety), disclose the synthesis of a new class of thermosetting elastomers: maleimide-capped polyimides. These polymers range from low melting solids to viscous liquids which can be functionalized with other curable moieties. These compounds have desirable properties for electronics applications: hydrophobicity, hydrolysis resistance, liquid state at room temperature (many) and low melt viscosities (solids), very high temperature resistance, and low modulus. Many of these compounds also have very low dielectric constant and low dielectric dissipation factor.

Advantageously, a variety of methods are available for polymerizing these thermoset maleimides. For example, they react by free-radical polymerization using standard peroxide initiators due to the electron-deficient nature of the maleimide double bond. They can undergo polymerization via Diels-Alder reactions and ene-reactions. Furthermore, the maleimide double bond also reacts with thiols, with amines by Michael addition reaction, and can react by anionic chain polymerization.

### Copper Clad Laminate

To prepare flexible, double-sided copper clad laminate, a piece of flexible film is typically cut from a large roll of film, adhesive is applied to both sides of the film and then copper foil is applied to the adhesive, this is followed by lamination process using heat and pressure. The flexible film must be able to withstand rolling for storage and subsequent unrolling to form FCCL, without cracking or deforming. There is a need for adhesive, flexible polymers, such as polyimides, for preparation of FCCL

### SUMMARY OF THE INVENTION

The present invention provides curable polyimides based on the condensation product of a diamine with a dianhydride followed cyclodehydration to form a polyamic acid, which is in turn followed by condensation with a curable moiety such as maleic anhydride as illustrated in Scheme 1 below.

The invention thus provides curable polyimide compounds having a structure according to the following Formula I:

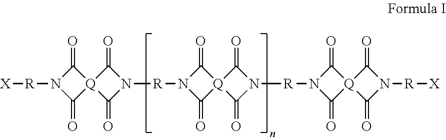

where R is selected from the group consisting of: substituted or unsubstituted aromatic, aliphatic, cycloaliphatic, alkenyl, polyether, polyester, polyamide, heteroaromatic, and siloxane, and combinations thereof; Q is selected from the group consisting of: substituted or unsubstituted aromatic, aliphatic, cycloaliphatic, alkenyl, polyether, polyester, polyamide, heteroaromatic, siloxane, and combinations thereof; X is a curable moiety; and n is 0 or an integer having the value from 1 to 100; with the proviso that, the average molecular weight of the material is greater than 20,000 Daltons, such as is 25,000 to 50,000 Dalton.

According to Formula I, X can be a moiety selected from the group consisting of: maleimide, benzoxazine, citraconimide, itaconimide, methacrylamide, acrylamide, phenolic, free-amine, carboxylic acid, alcohol, acrylate, methacrylate, oxazoline, vinyl ether, vinyl ester, allylic, vinylic, anhydride, and combinations thereof. In certain aspects, n is 20-100.

In certain embodiments, R is selected from:

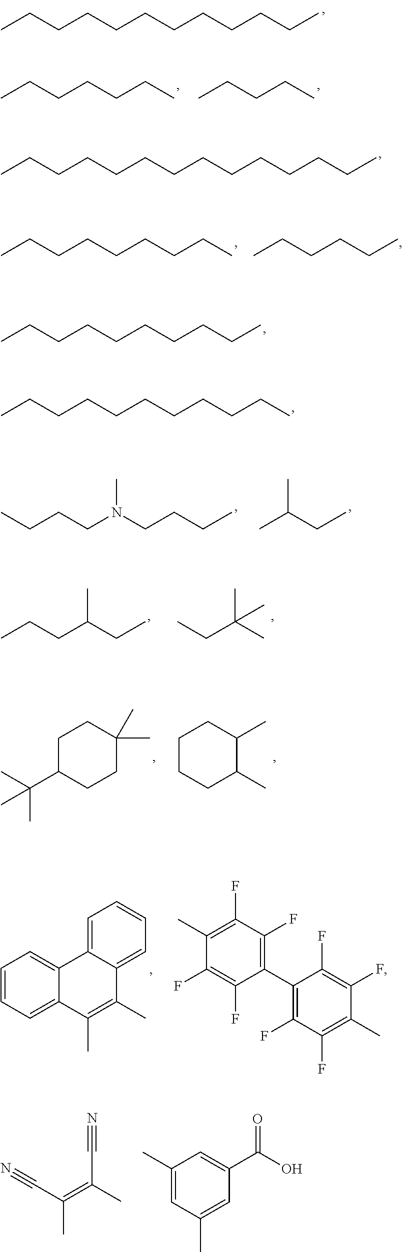

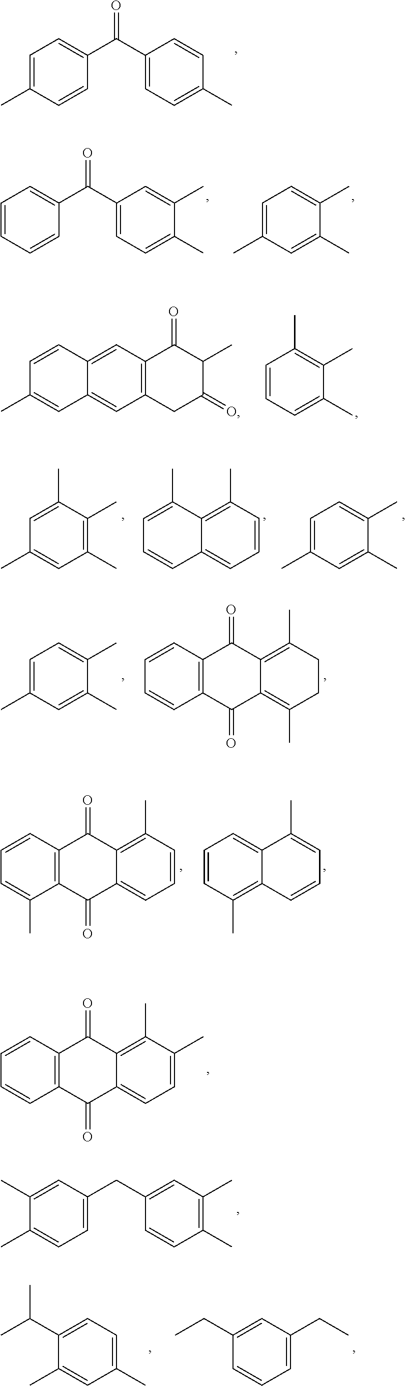

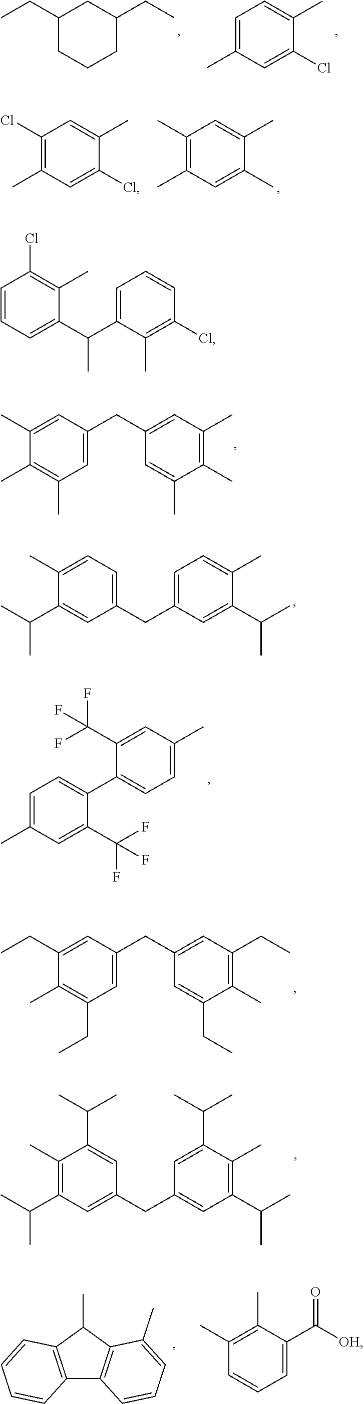

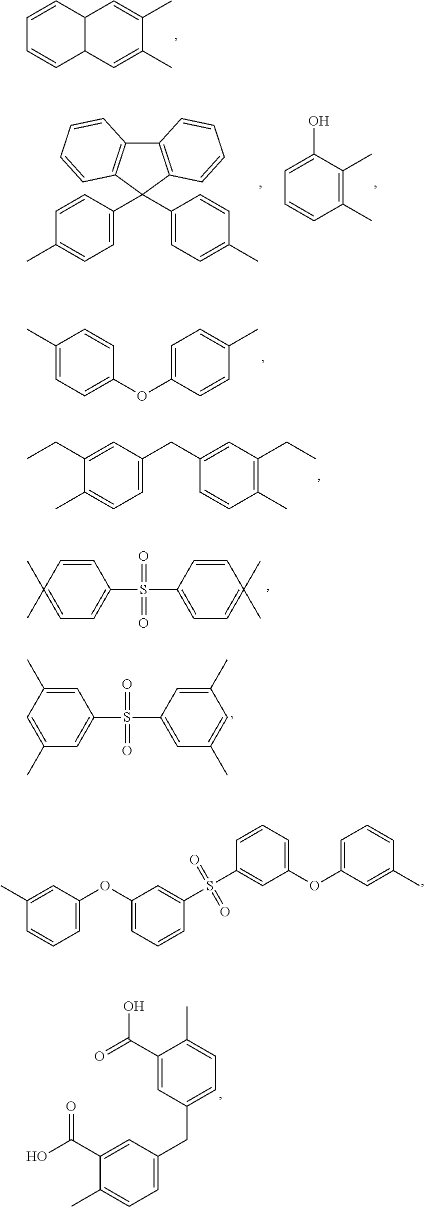

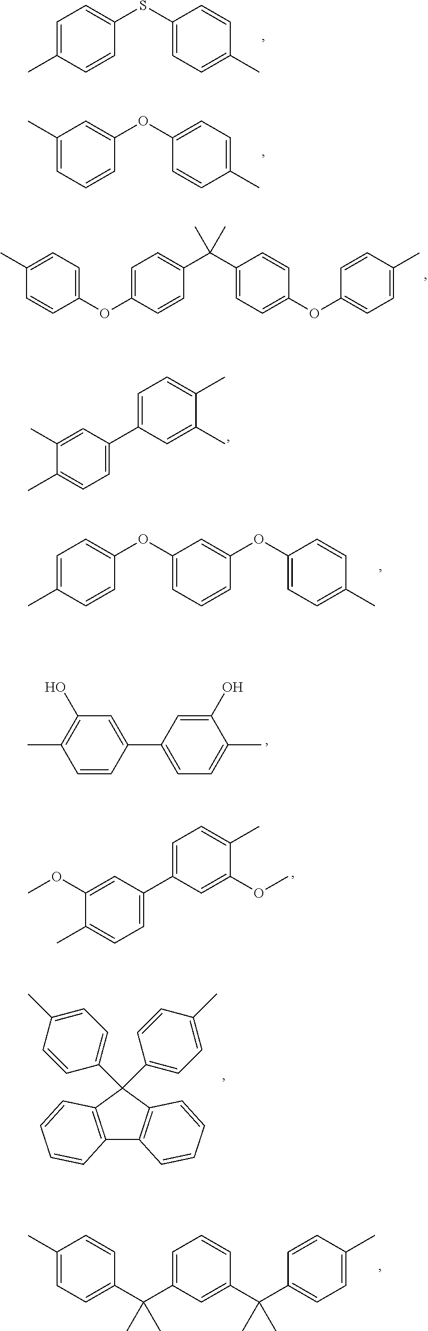

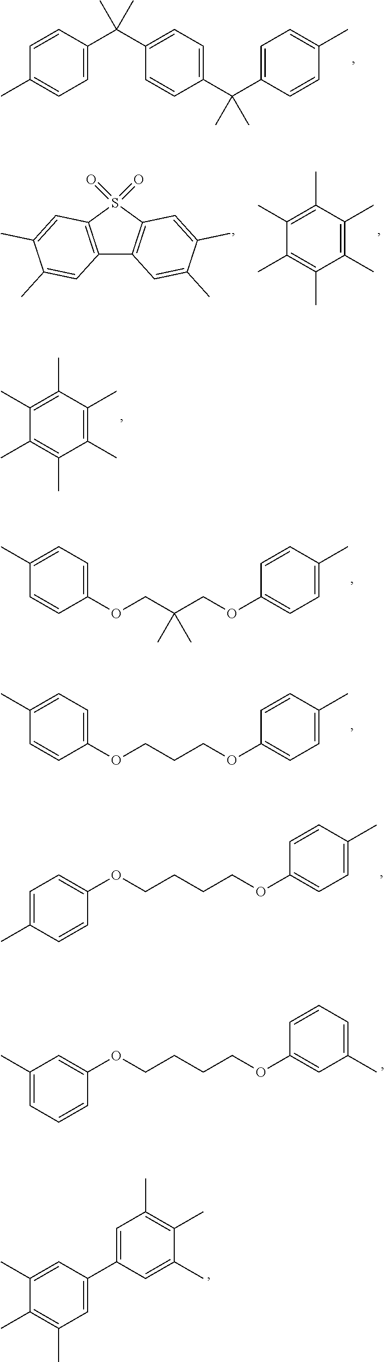

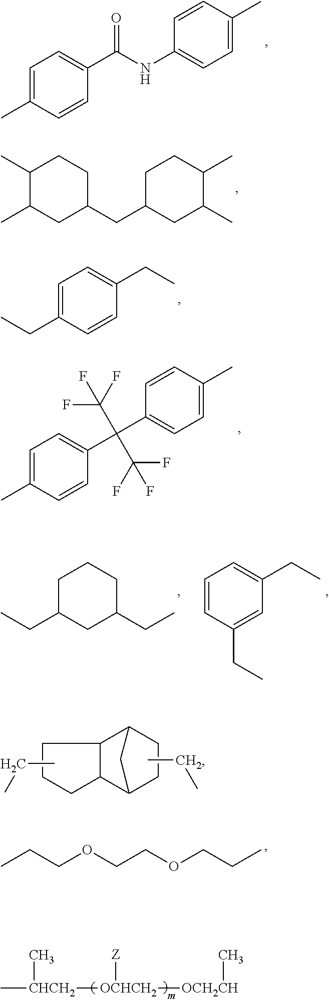

wherein Z is H or Me and m is an integer wherein the average molecular weight between 200 and 800 Daltons, or combinations thereof.

In certain embodiments, Q can be:

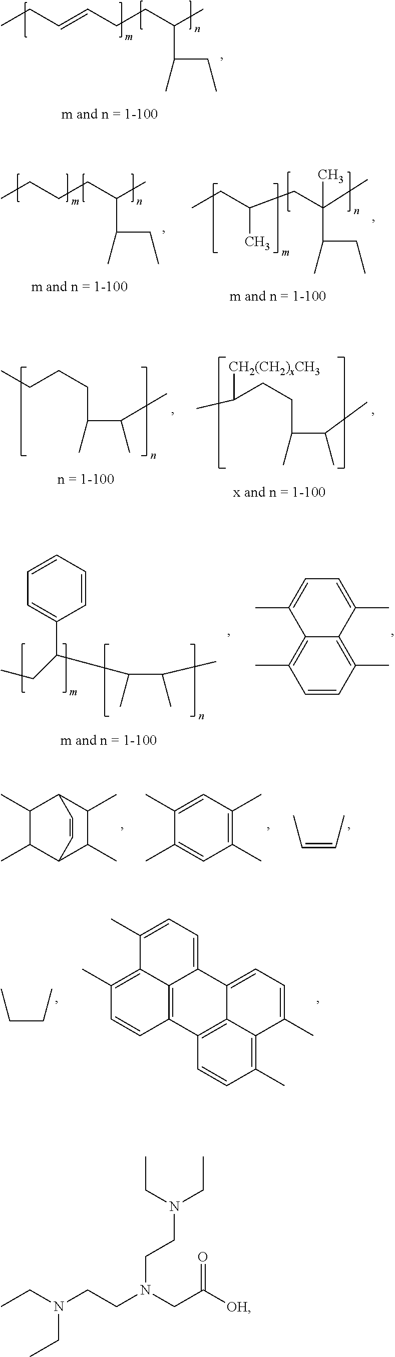

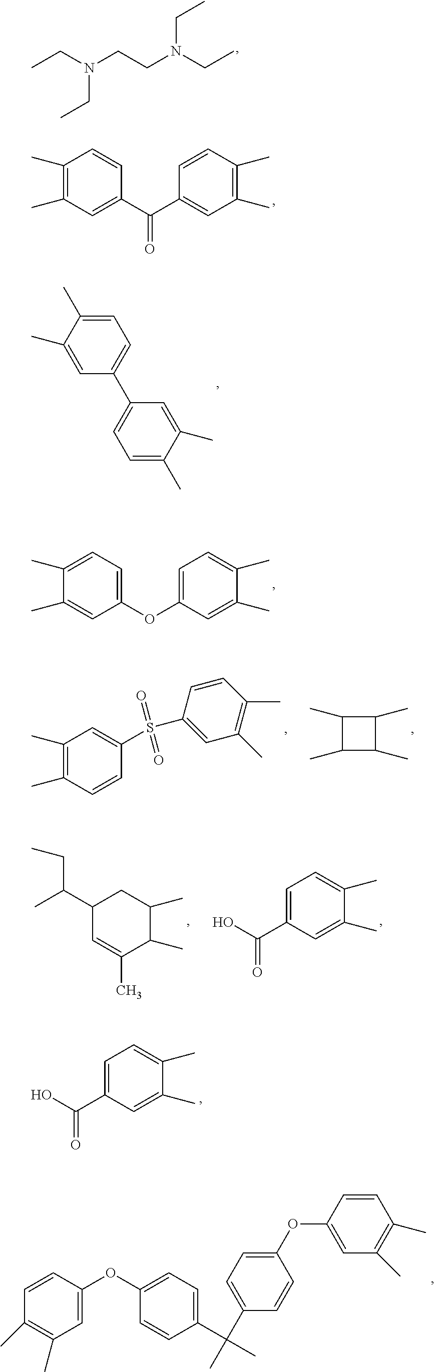

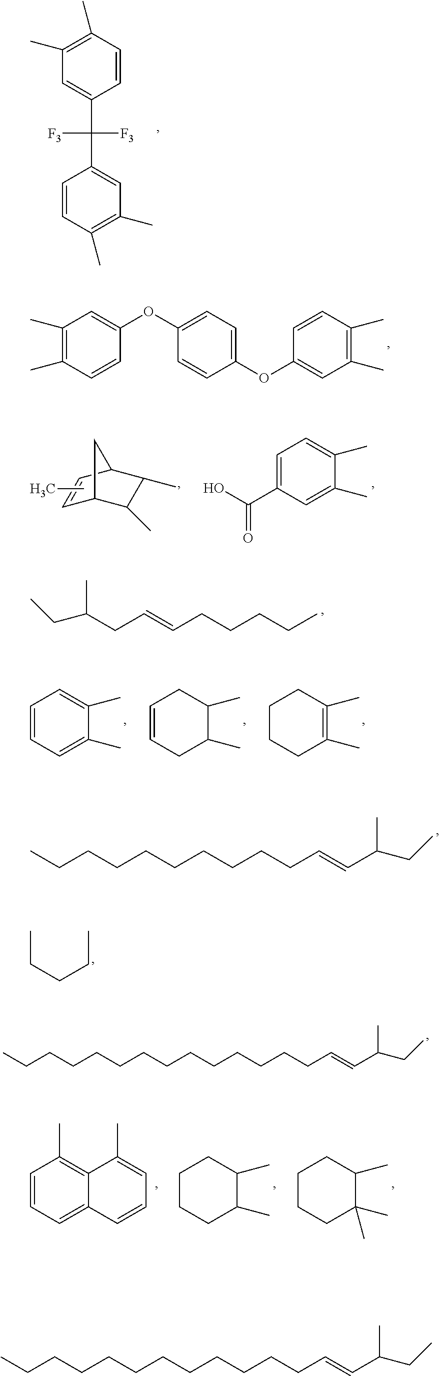

or combinations thereof.

The present invention also provides methods for synthesizing a high molecular weight, curable polyimide compound comprising the steps of: providing at least one diamine and at least one dianhydride; combining the at least one diamine with the at least one dianhydride in a solvent to form a mixture; refluxing the mixture, thereby forming a polyamic acid in the solution; azeotropically distilling the polyamic acid in the solution, thereby forming an amine-terminated polyimide in the solution; and functionalizing the amine-terminated polyimide by reacting the terminal amine groups to form curable terminal moieties on the polyimide, wherein the curable polyimide has a molecular weight greater than 20,000 Dalton; thereby synthesizing a high molecular weight, curable polyimide compound.

In certain embodiments, the at least one diamine, the at least one dianhydride or both are soluble in the solvent. In some aspects, the high molecular weight, curable polyimide is soluble in the solvent. In other embodiments, the polyamic acid, the polyimide and/or the curable polyimide is soluble in the solvent. In preferred aspects, the solvent is anisole.

To achieve high molecular weight, the at least one diamine is provided in slight excess of the at least one dianhydride, such as where the equivalent ratio of the at least one diamine to the at least one dianhydride is about 1.01:1 to about 1.10:1. In some aspects, the equivalent ratio of the at least one diamine to the at least one dianhydride is about 1.02:1 to about 1.09:1; about 1.03:1 to about 1.08:1; about 1.04:1 to about 1.07:1; or about 1.05:1 to about 1.06. In one embodiment, the at least one diamine to the at least one dianhydride is about 1.05:1.

The at least one diamine can be 1,10-diaminodecane; 1,12-diaminododecane; dimer diamine; hydrogenated dimer diamine; 1,2-diamino-2-methylpropane; 1,2-diaminocyclohexane; 1,2-diaminopropane; 1,3-diaminopropane; 1,4-diaminobutane; 1,5-diaminopentane; 1,7-diaminoheptane; 1,8-diaminomethane; 1,8-diaminooctane; 1,9-diaminononane; 3,3′-diamino-N-methyldipropylamine; diaminomaleonitrile; 1,3-diaminopentane; 9,10-diaminophenanthrene; 4,4′-diaminooctafluorobiphenyl; 3,5-diaminobenzoic acid; 3,7-diamino-2-methoxyfluorene; 4,4′-diaminobenzophenone; 3,4-diaminobenzophenone; 3,4-diaminotoluene; 2,6-diaminoanthroquinone; 2,6-diaminotoluene; 2,3-diaminotoluene; 1,8-diaminonaphthalene; 2,4-diaminotoluene; 2,5-diaminotoluene; 1,4-diaminoanthroquinone; 1,5-diaminoanthroquinone; 1,5-diaminonaphthalene; 1,2-diaminoanthroquinone; 2,4-cumenediamine; 1,3-bisaminomethylbenzene; 1,3-bisaminomethylcyclohexane; 2-chloro-1,4-diaminobenzene; 1,4-diamino-2,5-dichlorobenzene; 1,4-diamino-2,5-dimethylbenzene; 4,4′-diamino-2,2′-bistrifluoromethylbiphenyl; bis(amino-3-chlorophenyl)ethane; bis(4-amino-3,5-dimethylphenyl)methane; bis(4-amino-3,5-diethylphenyl)methane; bis(4-amino-2-chloro-3,5-diethylphenyl)methane; bis(4-amino-3,5-diisopropylphenyl)methane; bis(4-amino-3,5-methylisopropylphenyl)methane; bis(4-amino-3,5-bis(4-amino-3-ethylphenyl)methane; diaminofluorene; 4,4′-(9-Fluorenylidene)dianiline; diaminobenzoic acid; 2,3-diaminonaphthalene; 2,3-diaminophenol; bis(4-amino-3,5-dimethylphenyl)methane; bis(4-amino-3-methylphenyl)methane; bis(4-amino-3-ethylphenyl)methane; 4,4′-diaminophenylsulfone; 3,3′-diaminophenylsulfone; 2,2-bis(4-(4-aminophenoxy)phenyl)sulfone; 2,2-bis(4-(3-aminophenoxy)phenyl)sulfone; 4,4′-oxydianiline; 4,4′-diaminodiphenyl sulfide; 3,4′-oxydianiline; 2,2-bis(4-(4-aminophenoxy)phenyl)propane; 1,3-bis(4-aminophenoxy)benzene; 4,4′-bis(4-aminophenoxy)biphenyl; 4,4′-diamino-3,3′-dihydroxybiphenyl; 4,4′-diamino-3,3′-dimethylbiphenyl; 4,4′-diamino-3,3′-dimethoxybiphenyl; Bisaniline M; Bisaniline P; 9,9-bis(4-aminophenyl)fluorene; o-tolidine sulfone; methylene bis(anthranilic acid); 1,3-bis(4-aminophenoxy)-2,2-dimethylpropane; 1,3-bis(4-aminophenoxy)propane; 1,4-bis(4-aminophenoxy)butane; 1,5-bis(4-aminophenoxy)butane; 2,3,5,6-tetramethyl-1,4-phenylenediamine; 3,3′,5,5′-tetramehylbenzidine; 4,4′-diaminobenzanilide; 2,2-bis(4-aminophenyl)hexafluoropropane; polyoxyalkylenediamines; 1,3-cyclohexanebis(methylamine); m-xylylenediamine; p-xylylenediamine; bis(4-amino-3-methylcyclohexyl)methane; 1,2-bis(2-aminoethoxy)ethane; 3(4),8(9)-bis(aminomethyl)tricyclo(5.2.1.0^{2,6})decane or a combination thereof.

The at least one dianhydride can be polybutadiene-graft-maleic anhydride; polyethylene-graft-maleic anhydride; polyethylene-alt-maleic anhydride; polymaleic anhydride-alt-1-octadecene; polypropylene-graft-maleic anhydride: poly(styrene-co-maleic anhydride); pyromellitic dianhydride; maleic anhydride, succinic anhydride: 1,2,3,4-cyclobutanetetracarboxylic dianhydride; 1,4,5,8-naphthalenetetracarboxylic dianhydride; 3,4,9,10-pcrylenentetracarboxylic dianhydride; bicyclo(2.2.2)oct-7-ene-2,3,5,6-tetracarboxylic dianhydride; diethylenetriaminepentaacetic dianhydride; ethylenediaminetetraacetic dianhydride; 3,3′,4,4′-benzophenone tetracarboxylic dianhydride; 3,3′,4,4′-biphenyl tetracarboxylic dianhydride: 4,4′-oxydiphthalix anhydride; 3,3′,4,4′-diphenylsulfone tetracarboxylic dianhydride; 2,2′-bis(3,4-dicarboxyphenyl)hexafluoropropane dianhydride; 4,4′-bisphenol A diphthalic anhydride; 5-(2,5-dioxytetrahydro)-3-methyl-3-cyclohexene-1,2-dicarboxylic anhydride; ethylene glycol bis(trimellitic anhydride): hydroquinone diphthalic anhydride; allyl nadic anhydride; 2-octen-1-ylsuccinic anhydride; phthalic anhydride; 1,2,3,6-tetrahydrophthalic anhydride; 3,4,5,6-tetrahydrophthalic anhydride; 1,8-naphthalic anhydride: glutaric anhydride; dodecenylsuccinic anhydride; hexadecenylsuccinic anhydride; hexahydrophthalic anhydride; methylhexahydrophthalic anhydride; tetradecenylsuccinic anhydride; trimellitic anhydride; or a combination thereof.

Functionalizing the amine-terminated polyimide can include reacting the terminal amine groups with an anhydride, such as is maleic anhydride, where the terminal amine groups are converted to maleimide groups. Functionalizing the amine-terminated polyimide can also comprise reacting the terminal amine groups with a phenolic moiety and formaldehyde, wherein terminal amine groups are converted to benzoxazine groups. In other aspects, the curable terminal moieties are selected from maleimides, benzoxazines, citraconimides, itaconimides, methacrylamides, acrylamides, phenolics, free-amines, carboxylic acids, alcohols, acrylates, methacrylates, oxazolines, vinyl ethers, vinyl esters, allylics, vinylics, anhydrides, and combinations thereof.

The invention also provides curable polyimides, synthesized by the method of any of methods described herein. In certain aspects, curable polyimide compounds produced by the methods of the invention have a dielectric constant less than 3.0 and a dielectric dissipation factor less than 0.005.

The invention also provides compositions including one or more compounds described herein. The compositions can further include one or more fillers, coupling agents, co-curable reactive resins, coupling agents, adhesion promoters, catalysts and/or fire retardants.

The filler can be, for example, silica, perfluorotetraethylene, or a combination of perfluorotetraethylene and silica. In other aspects, they can be boron nitride, alumina, carbon black, graphite, carbon nanotubes, polyhedral oligomeric silsesquioxane (POSS), silver, copper, a metal alloy or a combination thereof.

The co-curable reactive resin can be an epoxy resin, a cyanate ester resin, a benzoxazine resin, a bismaleimide resin, a phenolic resin, a carboxyl resin, a liquid crystal polymer resin, a reactive ester resins, an acrylic resin or a tackifier.

The invention also provides methods for preparing a prepreg comprising containing a curable polyimide of the invention that include the steps of providing a reinforcing fiber (which can be woven or unwoven fabric); and immersing the reinforcing fiber in a liquid formulation of an uncured composition comprising a compound of the invention, thereby impregnating the reinforcing fiber, and thus preparing a prepreg. Thereafter, the prepreg can be drained to remove excess liquid formulation; and dried for storage. the prepreg.

Methods for preparing a copper-clad laminate (CCL) from the prepregs of the invention, in which copper is disposed on one or both sides of the prepreg. Disposing the copper can be by any method know in the art, such as electroplating copper to the one or the both sides of the prepreg or by laminating copper foil to the one or the both sides of the prepreg. Thus, the invention also provides CCLs that include a reinforcing fiber impregnated with a composition of disclosed herein, having copper disposed on one or both sides, which can be a CLL prepared by a method of the invention.

The invention also provides methods for preparing a printed circuit board (PCB) from a CCL of invention, by etching circuit traces in the copper disposed on the one or the both sides of the CCL,

Also provided are methods for preparing a flexible copper clad laminate (FCCL) comprising the steps of: providing a film comprising a curable polyimide compound of the invention and laminating copper foil to one or the both sides of the film, applying an adhesive to one of both sides of the film, with or without an adhesive layer between the film and the copper foil. In embodiments where the film is an adhesive film, the adhesive layer is not needed. The invention thus also provides FCCL prepared by this method of the invention.

The invention also provides thin, flexible electronic circuits, and methods for their preparation comprising the steps providing a FCCL disclosed herein, and etching circuit traces in the copper foil on one or both sides of the FCCL.

### BRIEF DESCRIPTION OF THE DRAWINGS

FIG. 1 is a schematic flow diagram illustrating the process of making a printed circuit board including preparing a prepreg, laminating copper onto the prepreg, and etching a circuit pattern on the copper-cladding. Arrows A-E indicate steps in the process.

FIG. 2 is a cross-sectional view through the structures at plane XVII of FIG. 9.

FIG. 3A is a schematic flow diagram illustrating the process of producing a one-sided flexible copper-clad laminate (FCCL) according to one embodiment of the invention that includes an adhesive layer. Arrows A and B indicate steps in the process.

FIG. 3B is a schematic flow diagram illustrating the process of producing a one-sided flexible copper-clad laminate (FCCL) according an embodiment of the invention that includes layers of adhesive. Arrows A and B indicate steps in the process.

FIG. 4A is a schematic flow diagram illustrating the process of producing a one-sided flexible copper-clad laminate (FCCL) according to one embodiment of the invention that omits an adhesive layer. Arrows A and B indicate steps in the process.

FIG. 4B is a schematic flow diagram illustrating the process of producing a one-sided flexible copper-clad laminate (FCCL) according an embodiment of the invention that excludes layers of adhesive. Arrows A and B indicate steps in the process.

### DETAILED DESCRIPTION

It is to be understood that both the foregoing general description and the following detailed description are exemplary and explanatory only and are not restrictive of the invention claimed. As used herein, the use of the singular includes the plural unless specifically stated otherwise. It is to be understood that as used in the specification and in the claims, “a” or “an” can mean one or more, depending upon the context in which it is used. Thus, reference to “a compound” can mean that at least one compound molecule is used, but typically refers to a plurality of compound molecules, which may be the same or different species. For example, “a compound having a structure according to the following Formula I” can refer to a single molecule or a plurality of molecules encompassed by the formula, as well all or a subset of the species the formula describes. As used herein, “or” means “and/or” unless stated otherwise. Furthermore, use of the term “including” as well as other forms, such as “includes,” and “included,” is not limiting.

The section headings used herein are for organizational purposes only and are not to be construed as limiting the subject matter described.

Unless specific definitions are provided, the nomenclatures utilized in connection with, and the laboratory procedures and techniques of analytical chemistry, synthetic organic and inorganic chemistry described herein are those known in the art, such as those set forth in “IUPAC Compendium of Chemical Terminology: IUPAC Recommendations (The Gold Book)” (McNaught ed.; International Union of Pure and Applied Chemistry, 2^{nd} Ed., 1997) and “Compendium of Polymer Terminology and Nomenclature: IUPAC Recommendations 2008” (Jones et al., eds; International Union of Pure and Applied Chemistry, 2009). Standard chemical symbols are used interchangeably with the full names represented by such symbols. Thus, for example, the terms “hydrogen” and “H” are understood to have identical meaning. Standard techniques may be used for chemical syntheses, chemical analyses, and formulation.

### Definitions

“About” as used herein means that a number referred to as “about” comprises the recited number plus or minus 1-10% of that recited number. For example, “about” 100 degrees can mean 95-105 degrees or as few as 99-101 degrees depending on the situation. Whenever it appears herein, a numerical range such as “1 to 20” refers to each integer in the given range; e.g., “1 to 20 carbon atoms” means that an alkyl group can contain only 1 carbon atom, 2 carbon atoms, 3 carbon atoms, etc., up to and including 20 carbon atoms (although the term “alkyl” also includes instances where no numerical range of carbon atoms is designated). Where “about” modifies a range expressed in non-integers, it means the recited number plus or minus 1-10% to the same degree of significant figures expressed. For example, about 1.50 to 2.50 mM can mean as little as 1.35 mM or as much as 2.75 mM or any amount in between in increments of 0.01. Where a range described herein includes decimal values, such as “1.2% to 10.5%”, the range refers to each decimal value of the smallest increment indicated in the given range; e.g. “1.2% to 10.5%” means that the percentage can be 1.2%, 1.3%, 1.4%, 1.5%, etc. up to and including 10.5%; while “1.20% to 10.50%” means that the percentage can be 1.20%, 1.21%, 1.22%, 1.23%, etc. up to and including 10.50%.

As used herein, the term “substantially” refers to a great extent or degree. More specifically, “substantially all” or equivalent expressions, typically refers to at least about 90%, frequently at least about 95%, often at least 99%, and more often at least about 99.9%. “Not substantially” refers to less than about 10%, frequently less than about 5%, and often less than about 1% such as less than 5%, less than 4%, less than 3%, less than 2%, or less than 1%. “Substantially free” or equivalent expressions, typically refers to less than about 10%, frequently less than about 5%, often less than about 1%, and in certain aspects less than about 0.1%.

“Adhesive” or “adhesive compound” as used herein, refers to any substance that can adhere or bond two items together. Implicit in the definition of an “adhesive composition” or “adhesive formulation” is the fact that the composition or formulation is a combination or mixture of more than one species, component or compound, which can include adhesive monomers, oligomers, and/or polymers along with other materials, whereas an “adhesive compound” refers to a single species, such as an adhesive polymer or oligomer.

More specifically, “adhesive composition” refers to un-cured mixtures in which the individual components in the mixture retain the chemical and physical characteristics of the original individual components of which the mixture is made. Adhesive compositions are typically malleable and may be liquids, pastes, gels, films or another form that can be applied to an item so that it can be bonded to another item.

“Photoimageable”, as used herein, refers to the ability of a compound or composition to be selectively cured only in areas exposed to light. The exposed areas of the compound are thereby rendered cured and insoluble, while the unexposed area of the compound or composition remain un-cured and therefore soluble in a developer solvent. Typically, this operation is conducted using ultraviolet light as the light source and a photomask as the means to define where the exposure occurs. The selective patterning of dielectric layers on a silicon wafer can be carried out in accordance with various photolithographic techniques known in the art. In one method, a photosensitive polymer film is applied over the desired substrate surface and dried. A photomask containing the desired patterning information is then placed in close proximity to the photoresist film. The photoresist is irradiated through the overlying photomask by one of several types of imaging radiation including UV light, e-beam electrons, x-rays, or ion beam. Upon exposure to the radiation, the polymer film undergoes a chemical change (crosslinks) with concomitant changes in solubility. After irradiation, the substrate is soaked in a developer solution that selectively removes the non-crosslinked or unexposed areas of the film. Photolithography is widely used to produce circuit traces on copper foil adhered to a substrate such as a prepreg to produce a printed circuit board or to a flexible film in a flexi copper clad laminate. The photoresist protects the copper that will become the circuit while the non-circuit areas are selectively removed.

“Conformal coatings” as used herein, refers to a material applied to electronic circuitry to act as protection against moisture, dust, chemicals, and temperature extremes that, if uncoated, could result in damage or failure of the electronics to function properly. Typically, the electronic circuitry or assemblies thereof is coated with a layer of transparent conformal coating to protect the electronics from harsh environment. In some instances, the conformal coating is transparent such that the circuitry can be visually inspected. Suitably chosen conformal coatings can also reduce the effects of mechanical stress, vibration and extreme temperatures. For example, in a chip-on-board packaging process, a silicon die is mounted on the board with adhesive or a soldering, and then electrically connected by wire bonding. To protect the very delicate package, the whole chip-on-board is encapsulated in a conformal coating, commonly referred to as a “glob top”.

“Breakdown voltage”, as used herein, refers to the minimum voltage that causes a portion of an insulator to become electrically conductive. “High breakdown voltage” is at least about 100 V to at least about 900 V, such as 200V, 300V, 400V, 500V, 600V, 700V, 800V, 900V, 1,000V or higher.

“Electric power” is the rate, per unit time, at which electrical energy is transferred by an electric circuit. It is the rate of doing work. In electric circuits, power is measured in Watts (W) and is a function of both voltage and current:

P=IE

where P=power (in watts); I=current (in amperes) and E=voltage (in volts). Since Electric power generally generates heat “high power” is often used to refer to devices and applications that generate heat in excess of 100° C.

“High frequency” or “HF”, as used herein, refers to the range of radio frequency electromagnetic waves between 3 and 30 megahertz (MHz).

“Dielectric”, as used herein, refers to an insulating material that has the property of transmitting electric force without conduction. When a dielectric material is placed in an electric field, electric charges do not flow through the material as they do in an electrical conductor but only slightly shift from their average equilibrium positions causing dielectric polarization. Because of dielectric polarization, positive charges are displaced in the direction of the field and negative charges shift in the direction opposite to the field. This creates an internal electric field that reduces the overall field within the dielectric itself.

As used herein the term “dielectric constant” and abbreviation “Dk” or “relative permittivity”, is the ratio of the permittivity (a measure of electrical resistance) of a substance to the permittivity of free space (which is given a value of 1). In simple terms, the lower the Dk of a material, the better it will act as an insulator. As used herein, “low dielectric constant” refers to materials with a Dk less than that of silicon dioxide, which has Dk of 3.9. Thus, “low dielectric constant refers” to a Dk of less than 3.9, typically, less than about 3.5, and most often less than about 3.0.

As used herein the term “dissipation dielectric factor”, “dissipation dielectric factor”, and abbreviation “D” are used herein to refer to a measure of loss-rate of energy in a thermodynamically open, dissipative system. In simple terms, Df is a measure of how inefficient the insulating material of a capacitor is. It typically measures the heat that is lost when an insulator such as a dielectric is exposed to an alternating field of electricity. The lower the Df of a material, the better its efficiency. “Low dissipation dielectric factor” typically refers to a Df of less than about 0.01 at 1 GHz frequency, frequently less than about 0.005 at 1 GHz frequency, and most often 0.001 or lower at 1 GHz frequency.

“Interlayer Dielectric Layer” or “ILD” refer to a layer of dielectric material disposed over a first pattern of conductive traces, separating it from a second pattern of conductive traces, which can be stacked on top of the first. Often, ILD layers are patterned or drilled to provide openings (referred to as “vias”, short for “vertical interconnect access” channels) allowing electrical contact between the first and second patterns of conductive traces in specific regions or in layers of a multilayer printed circuit board. Other regions of such ILD layers are devoid of vias to strategically prevent electrical contact between the conductive traces of first and second patterns or layers.

In electronics, “leakage” is the gradual transfer of electrical energy across a boundary normally viewed as insulating, such as the spontaneous discharge of a charged capacitor, magnetic coupling of a transformer with other components, or flow of current across a transistor in the “off” state or a reverse-polarized diode. Another type of leakage can occur when current leaks out of the intended circuit, instead flowing through some alternate path. This sort of leakage is undesirable because the current flowing through the alternate path can cause damage, fires, RF noise, or electrocution.

“Leakage current” as used herein, refers to the gradual loss of energy from a charged capacitor, primarily caused by electronic devices attached to the capacitor, such as transistors or diodes, which conduct a small amount of current even when they are turned off. “Leakage current” also refers any current that flows when the ideal current is zero. Such is the case in electronic assemblies when they are in standby, disabled, or “sleep” mode (standby power). These devices can draw one or two microamperes while in their quiescent state compared to hundreds or thousands of milliamperes while in full operation. These leakage currents are becoming a significant factor to portable device manufacturers because of their undesirable effect on battery run time for the consumer.

“Thermoplastic”, as used herein, refers to the ability of a compound, composition or other material (e.g. a plastic) to dissolve in a suitable solvent or to melt to a liquid when heated and freeze to a solid, often brittle and glassy, state when cooled sufficiently.

“Thermoset”, as used herein, refers to the ability of a compound, composition or other material, to irreversibly “cue”, resulting in a single three-dimensional network that has greater strength and less solubility compared to the un-cured material. Thermoset materials are typically polymers that may be cured, for example, through heat (e.g. above 200° C.), via a chemical reaction (e.g. epoxy ring-opening, free-radical polymerization) or through irradiation (with e.g., visible light, UV light, electron beam radiation, ion-beam radiation, or X-ray irradiation).

Thermoset materials, such as thermoset polymers and resins, are typically liquid or malleable forms prior to curing, and therefore may be molded or shaped into their final form, and/or used as adhesives. Curing transforms the thermoset material into a rigid, infusible and insoluble solid or rubber by a cross-linking process. Energy and/or catalysts are typically added to the uncured thermoset that cause the thermoset molecules to react at chemically active sites (e.g., unsaturated or epoxy sites), thereby linking the thermoset molecules into a rigid, 3-dimensional structure. The cross-linking process forms molecules with higher molecular weight and resulting higher melting point. During the curing reaction, when the molecular weight of the polymer has increased to a point that the melting point is higher than the surrounding ambient temperature, the polymer becomes a solid material.

“Cured adhesive,” “cured adhesive composition” or “cured adhesive compound” refers to adhesive components and mixtures obtained from reactive curable original compounds or mixtures thereof, that have undergone a chemical and/or physical changes such that the original compounds or mixtures are transformed into a solid, substantially non-flowing material. A typical curing process may involve crosslinking.

“Curable” means that an original compound or composition can be transformed into a solid, substantially non-flowing material by means of chemical reaction, crosslinking, radiation crosslinking, or a similar process. Thus, adhesive compounds and compositions of the invention are curable, but unless otherwise specified, the original compounds or compositions are not cured.

As used herein, terms “functionalize”, “functionalized” and “functionalization” refer to the addition or inclusion of a moiety (“functional moiety” or “functional group”) to a molecule that imparts a specific property, often the ability of the functional group to react with other molecules in a predictable and/or controllable way. In certain embodiments of the invention, functionalization is imparted to a terminus of the molecule through the addition or inclusion of a terminal group, X. In other embodiments, internal and/or pendant functionalization can be included in the polyimides of the invention. In some aspects of the invention, the functional group is a “curable group” or “curable moiety”, which is a group or moiety that allows the molecule to undergo a chemical and/or physical change such that the original molecule is transformed into a solid, substantially non-flowing material. “Curable groups” or “curable moieties” may facilitate crosslinking.

“Cross-linking,” as used herein, refers to the attachment of two or more oligomer or longer polymer chains by bridges of an element, a molecular group, a compound, or another oligomer or polymer. Crosslinking may take place upon heating or exposure to light; some crosslinking processes may occur at room temperature or a lower temperature. As cross-linking density is increased, the properties of a material can be changed from thermoplastic to thermosetting.

“Rollable” and “rollability”, as used herein, refers to the ability of a material, such as a polymer film, typically a thin polymer film about 10 μm to about 2.0 mm thickness and to be rolled into a cylindrical shape without resistance or cracking. Typically, rollable materials of the invention can be rolled, unrolled and repeatedly rolled again without damage. Very flexible polymers, such as the high molecular weight polyimides of the invention, are required to withstand such manipulation. “Rollability” is an indication that the material will also withstand the rigorous handling that flexible printed circuits may encounter in use.

As used herein, “B-stageable” refers to the properties of an adhesive having a first solid phase followed by a tacky rubbery stage at elevated temperature, followed by yet another solid phase at an even higher temperature. The transition from the tacky rubbery stage to the second solid phase is thermosetting. However, prior to thermosetting, the material behaves similarly to a thermoplastic material. Thus, such adhesives allow for low lamination temperatures while providing high thermal stability.

The term “monomer” refers to a molecule that can undergo polymerization or copolymerization thereby contributing constitutional units to the essential structure of a macromolecule (i.e., a polymer).

“Polymer” and “polymer compound” are used interchangeably herein, to refer generally to the combined the products of a single chemical polymerization reaction. Polymers are produced by combining monomer subunits into a covalently bonded chain. Polymers that contain only a single type of monomer are known as “homopolymers,” while polymers containing a mixture of two or more different monomers are known as “copolymers”.

The term “copolymers” is inclusive of products that are obtained by copolymerization of two monomer species, those obtained from three monomers species (terpolymers), those obtained from four monomers species (quaterpolymers), and those obtained from five or more monomer species. It is well known in the art that copolymers synthesized by chemical methods include, but are not limited to, molecules with the following types of monomer arrangements:
alternating copolymers, which contain regularly alternating monomer residues;
periodic copolymers, which have monomer residue types arranged in a repeating sequence;
random copolymers, which have a random sequence of monomer residue types;
statistical copolymers, which have monomer residues arranged according to a known statistical rule;
block copolymers, which have two or more homopolymer subunits linked by covalent bonds. The blocks of homopolymer within block copolymers, for example, can be of any length and can be blocks of uniform or variable length. Block copolymers with two or three distinct blocks are called diblock copolymers and triblock copolymers, respectively; and
star copolymers, which have chains of monomer residues having different constitutional or configurational features that are linked through a central moiety.

The skilled artisan will appreciate that a single copolymer molecule may have different regions along its length that can be characterized as an alternating, periodic, random, etc. A copolymer product of a chemical polymerization reaction may contain individual polymeric molecules and fragments that each differ in the arrangement of monomer units. The skilled artisan will further be knowledgeable in methods for synthesizing each of these types of copolymers, and for varying reaction conditions to favor one type over another.

Furthermore, the length of a polymer chain according to the present invention will typically vary over a range or average size produced by a particular reaction. The skilled artisan will be aware, for example, of methods for controlling the average length of a polymer chain produced in a given reaction and also of methods for size-selecting polymers after they have been synthesized.

“Polydispersity index” (PDI) or “heterogeneity index”, is a measure of the distribution of molecular mass in a given polymer sample. PDI is calculated by the following formula:

PDI=M_{w}/Mₙ,

where M_{w} is the weight average molecular weight and Mₙ is the number average molecular weight.

Unless a more restrictive term is used, “polymer” is intended to encompass homopolymers, and copolymers having any arrangement of monomer subunits as well as copolymers containing individual molecules having more than one arrangement. With respect to length, unless otherwise indicated, any length limitations recited for the polymers described herein are to be considered averages of the lengths of the individual molecules in polymer.

“Thermoplastic elastomer” or “TPE”, as used herein refers to a class of copolymers that consist of materials with both thermoplastic and elastomeric properties.

“Hard blocks” or “hard segments” as used herein refer to a block of a copolymer (typically a thermoplastic elastomer) that is hard at room temperature by virtue of a high melting point (Tm) or T_{g}. By contrast, “soft blocks” or “soft segments” have a T_{g} below room temperature.

As used herein, “oligomer” or “oligomeric” refers to a polymer having a finite and moderate number of repeating monomers structural units. Oligomers of the invention typically have 2 to about 100 repeating monomer units; frequently 2 to about 30 repeating monomer units; and often 2 to about 10 repeating monomer units; and usually have a molecular weight up to about 3,000.

The skilled artisan will appreciate that oligomers and polymers may, depending on the availability of polymerizable groups or side chains, subsequently be incorporated as monomers in further polymerization or crosslinking reactions.

As used herein, “aliphatic” refers to any alkyl, alkenyl, cycloalkyl, or cycloalkenyl moiety.

“Aromatic hydrocarbon” or “aromatic” as used herein, refers to compounds having one or more benzene rings.

“Alkane,” as used herein, refers to saturated straight-chain, branched or cyclic hydrocarbons having only single bonds. Alkanes have general formula CₙH₂ₙ₊₂.

“Cycloalkane,” refers to an alkane having one or more rings in its structure.

As used herein, “alkyl” refers to straight or branched chain hydrocarbyl groups having from 1 to about 500 carbon atoms. “Lower alkyl” refers generally to alkyl groups having 1 to 6 carbon atoms. The terms “alkyl” and “substituted alkyl” include, respectively, substituted and unsubstituted C₁-C₅₀₀ straight chain saturated aliphatic hydrocarbon groups, substituted and unsubstituted C₂-C₂₀₀ straight chain unsaturated aliphatic hydrocarbon groups, substituted and unsubstituted C₄-C₁₀₀ branched saturated aliphatic hydrocarbon groups, substituted and unsubstituted C₁-C₅₀₀ branched unsaturated aliphatic hydrocarbon groups.

For example, the definition of “alkyl” includes but is not limited to: methyl (Me), ethyl (Et), propyl (Pr), butyl (Bu), pentyl, hexyl, heptyl, octyl, nonyl, decyl, undecyl, ethenyl, propenyl, butenyl, penentyl, hexenyl, heptenyl, octenyl, nonenyl, decenyl, undecenyl, isopropyl (i-Pr), isobutyl (i-Bu), tert-butyl (t-Bu), sec-butyl (s-Bu), isopentyl, neopentyl, cyclopropyl, cyclobutyl, cyclopentyl, cyclohexyl, cycloheptyl, cyclooctyl, cyclopentenyl, cyclohexenyl, cycloheptenyl, cyclooctenyl, methylcyclopropyl, ethylcyclohexenyl, butenylcyclopentyl, tricyclodecyl, adamantyl, and norbornyl.

“Substituted” refers to compounds and moieties bearing “substituents” that include but are not limited to alkyl (e.g. C₁₋₁₀ alkyl), alkenyl, alkynyl, hydroxy, oxo, alkoxy, mercapto, cycloalkyl, substituted cycloalkyl, heterocyclic, substituted heterocyclic, aryl, substituted aryl (e.g., aryl C₁₋₁₀alkyl or aryl C₁₋₁₀ alkyloxy), heteroaryl, substituted heteroaryl (e.g., heteroarylC₁₋₁₀alkyl), aryloxy, C₁₋₁₀ alkyloxy C₁₋₁₀ alkyl, aryl C₁₋₁₀ alkyloxyC₁₋₁₀ alkyl, C₁₋₁₀ alkylthioC₁₋₁₀ alkyl, aryl C₁₋₁₀ alkylthio C₁₋₁₀ alkyl, C₁₋₁₀ alkylamino C₁₋₁₀ alkyl, aryl C₁₋₁₀ alkylamino C₁₋₁₀ alkyl, N-aryl-N—C₁₋₁₀ alkylamino C₁₋₁₀ alkyl, C₁₋₁₀ alkylcarbonyl C₁₋₁₀ alkyl, aryl C₁₋₁₀ alkylcarbonyl C₁₋₁₀ alkyl, C₁₋₁₀ alkylcarboxy C₁₋₁₀ alkyl, aryl C₁₋₁₀ alkylcarboxy C₁₋₁₀ alkyl, C₁₋₁₀ alkylcarbonylamino C₁₋₁₀ alkyl, and aryl C₁₋₁₀ alkylcarbonylamino C₁₋₁₀ alkyl, substituted aryloxy, halo, haloalkyl (e.g., trihalomethyl), cyano, nitro, nitrone, amino, amido, carbamoyl, ═O, ═CH—, —C(O)H, —C(O)O—, —C(O)—, —S—, —S(O)₂, —OC(O)—O—, —NR—C(O), —NR—C(O)—NR, —OC(O)—NR, where R is H or lower alkyl, acyl, oxyacyl, carboxyl, carbamate, sulfonyl, sulfonamide, sulfuryl, C₁₋₁₀ alkylthio, aryl C₁₋₁₀ alkylthio, C₁₋₁₀ alkylamino, aryl C₁₋₁₀ alkylamino, N-aryl-N—C₁₋₁₀ alkylamino, C₁₋₁₀ alkyl carbonyl, aryl C₁₋₁₀ alkylcarbonyl, C₁₋₁₀ alkylcarboxy, aryl C₁₋₁₀ alkylcarboxy, C₁₋₁₀ alkyl carbonylamino, aryl C₁₋₁₀ alkylcarbonylamino, tetrahydrofuryl, morpholinyl, piperazinyl, and hydroxypyronyl.

In addition, as used herein “C₃₆” refers to all possible structural isomers of a 36-carbon aliphatic moiety, including branched isomers and cyclic isomers with up to three carbon-carbon double bonds in the backbone. A non-limiting example of a moiety that “C₃₆” refers to is the moiety comprising a cyclohexane core and four long “arms” attached to the core, as illustrated below:

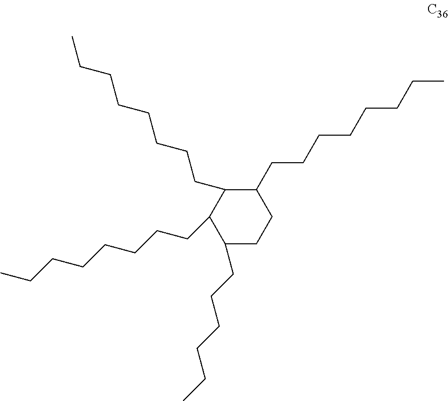 [SMILES: CCCCCCCCC1CCC(CCCCCC)C(CCCCCCCC)C1CCCCCCCC]

As used herein, “cycloalkyl” refers to cyclic ring-containing groups containing about 3 to about 20 carbon atoms, typically 3 to about 15 carbon atoms. In certain embodiments, cycloalkyl groups have about 4 to about 12 carbon atoms, and in yet further embodiments, cycloalkyl groups have about 5 to about 8 carbon atoms. “Substituted cycloalkyl” refers to cycloalkyl groups bearing one or more substituents as set forth above.

As used herein, the term “aryl” refers to an unsubstituted, mono-, di- or trisubstituted monocyclic, polycyclic, biaryl aromatic groups covalently attached at any ring position capable of forming a stable covalent bond, certain preferred points of attachment being apparent to those skilled in the art (e.g., 3-phenyl, 4-naphtyl and the like). “Substituted aryl” refers to aryl groups bearing one or more substituents as set forth above.

Specific examples of moieties encompassed by the definition of “aryl” include but are not limited to phenyl, biphenyl, naphthyl, dihydronaphthyl, tetrahydronaphthyl, indenyl, indanyl, azulenyl, anthryl, phenanthryl, fluorenyl, pyrenyl and the like.

As used herein, “arylene” refers to a divalent aryl moiety. “Substituted arylene” refers to arylene moieties bearing one or more substituents as set forth above.

As used herein, “alkylaryl” refers to alkyl-substituted aryl groups and “substituted alkylaryl” refers to alkylaryl groups further bearing one or more substituents as set forth above.

As used herein, “arylalkyl” refers to aryl-substituted alkyl groups and “substituted arylalkyl” refers to arylalkyl groups further bearing one or more substituents as set forth above. Examples include but are not limited to (4-hydroxyphenyl) ethyl, or (2-aminonaphthyl) hexenyl.

As used herein, “arylalkenyl” refers to aryl-substituted alkenyl groups and “substituted arylalkenyl” refers to arylalkenyl groups further bearing one or more substituents as set forth above.

As used herein, “arylalkynyl” refers to aryl-substituted alkynyl groups and “substituted arylalkynyl” refers to arylalkynyl groups further bearing one or more substituents as set forth above.

As used herein, “aroyl” refers to aryl-carbonyl species such as benzoyl and “substituted aroyl” refers to aroyl groups further bearing one or more substituents as set forth above.

As used herein, “hetero” refers to groups or moieties containing one or more non-carbon heteroatoms, such as N, O, Si and S. Thus, for example “heterocyclic” refers to cyclic (i.e., ring-containing) groups having e.g. N, O, Si or S as part of the ring structure, and having 3 to 14 carbon atoms. “Heteroaryl” and “heteroalkyl” moieties are aryl and alkyl groups, respectively, containing e.g. N, O, Si or S as part of their structure. The terms “heteroaryl”, “heterocycle” or “heterocyclic” refer to a monovalent unsaturated group having a single ring or multiple condensed rings, from 1 to 8 carbon atoms and from 1 to 4 hetero atoms selected from nitrogen, sulfur or oxygen within the ring.

The definition of heteroaryl includes but is not limited to thienyl, benzothienyl, isobenzothienyl, 2,3-dihydrobenzothienyl, furyl, pyranyl, benzofuranyl, isobenzofuranyl, 2,3-dihydrobenzofuranyl, pyrrolyl, pyrrolyl-2,5-dione, 3-pyrrolinyl, indolyl, isoindolyl, 3H-indolyl, indolinyl, indolizinyl, indazolyl, phthalimidyl (or isoindoly-1,3-dione), imidazolyl, 2H-imidazolinyl, benzimidazolyl, pyridyl, pyrazinyl, pyradazinyl, pyrimidinyl, triazinyl, quinolyl, isoquinolyl, 4H-quinolizinyl, cinnolinyl, phthalazinyl, quinazolinyl, quinoxalinyl, 1,8-naphthyridinyl, pteridinyl, carbazolyl, acridinyl, phenazinyl, phenothiazinyl, phenoxazinyl, chromanyl, benzodioxolyl, piperonyl, purinyl, pyrazolyl, triazolyl, tetrazolyl, thiazolyl, isothiazolyl, benzthiazolyl, oxazolyl, isoxazolyl, benzoxazolyl, oxadiazolyl, thiadiazolyl, pyrrolidinyl-2,5-dione, imidazolidinyl-2,4-dione, 2-thioxo-imidazolidinyl-4-one, imidazolidinyl-2,4-dithione, thiazolidinyl-2,4-dione, 4-thioxo-thiazolidinyl-2-one, piperazinyl-2,5-dione, tetrahydro-pyridazinyl-3,6-dione, 1,2-dihydro-[1,2,4,5]tetrazinyl-3,6-dione, [1,2,4,5]tetrazinanyl-3,6-dione, dihydro-pyrimidinyl-2,4-dione, pyrimidinyl-2,4,6-trione, 1H-pyrimidinyl-2,4-dione, 5-iodo-1H-pyrimidinyl-2,4-dione, 5-chloro-1H-pyrimidinyl-2,4-dione, 5-methyl-1H-pyrimidinyl-2,4-dione, 5-isopropyl-1H-pyrimidinyl-2,4-dione, 5-propynyl-1H-pyrimidinyl-2,4-dione, 5-trifluoromethyl-1H-pyrimidinyl-2,4-dione, 6-amino-9H-purinyl, 2-amino-9H-purinyl, 4-amino-1H-pyrimidinyl-2-one, 4-amino-5-fluoro-1H-pyrimidinyl-2-one, 4-amino-5-methyl-1H-pyrimidinyl-2-one, 2-amino-1,9-dihydro-purinyl-6-one, 1,9-dihydro-purinyl-6-one, 1H-[1,2,4]triazolyl-3-carboxylic acid amide, 2,6-diamino-N.sub.6-cyclopropyl-9H-purinyl, 2-amino-6-(4-methoxyphenylsulfanyl)-9H-purinyl, 5,6-dichloro-1H-benzoimidazolyl, 2-isopropylamino-5,6-dichloro-1H-benzoimidazolyl, and 2-bromo-5,6-dichloro-1H-benzoimidazolyl. Furthermore, the term “saturated heterocyclic” represents an unsubstituted, mono-, di- or trisubstituted monocyclic, polycyclic saturated heterocyclic group covalently attached at any ring position capable of forming a stable covalent bond, certain preferred points of attachment being apparent to those skilled in the art (e.g., 1-piperidinyl, 4-piperazinyl and the like).

Hetero-containing groups may also be substituted. For example, “substituted heterocyclic” refers to a ring-containing group having 3 to 14 carbon atoms that contains one or more heteroatoms and also bears one or more substituents set forth above.

As used herein, the term “phenol” includes compounds having one or more phenolic functions per molecule, as illustrated below:

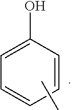

The terms aliphatic, cycloaliphatic and aromatic, when used to describe phenols, refers to phenols to which aliphatic, cycloaliphatic and aromatic residues or combinations of these backbones are attached by direct bonding or ring fusion.

As used herein, “alkenyl,” “alkene” or “olefin” refers to straight or branched chain unsaturated hydrocarbyl groups having at least one carbon-carbon double bond and having about 2 to 500 carbon atoms. In certain embodiments, alkenyl groups have about 5 to about 250 carbon atoms, about 5 to about 100 carbon atoms, about 5 to about 50 carbon atoms or about 5 to about 25 carbon atoms. In other embodiments, alkenyl groups have about 6 to about 500 carbon atoms, about 8 to about 500 carbon atoms, about 10 to about 500 carbon atoms, about 20 to about 500 carbon atoms, about 50 to about 500 carbon atoms. In yet further embodiments, alkenyl groups have about 6 to about 100 carbon atoms, about 10 to about 100 carbon atoms, about 20 to about 100 carbon atoms, or about 50 to about 100 carbon atoms, while in other embodiments, alkenyl groups have about 6 to about 50 carbon atoms, about 6 to about 25 carbon atoms, about 10 to about 50 carbon atoms, or about 10 to about 25 carbon atoms. “Substituted alkenyl” refers to alkenyl groups further bearing one or more substituents as set forth above.

As used herein, “alkylene” refers to a divalent alkyl moiety, and “oxyalkylene” refers to an alkylene moiety containing at least one oxygen atom instead of a methylene (CH₂) unit. “Substituted alkylene” and “substituted oxyalkylene” refer to alkylene and oxyalkylene groups further bearing one or more substituents as set forth above.

As used herein, “alkynyl” refers to straight or branched chain hydrocarbyl groups having at least one carbon-carbon triple bond and having about 2 to about 100 carbon atoms, typically about 4 to about 50 carbon atoms, and frequently about 8 to about 25 carbon atoms. “Substituted alkynyl” refers to alkynyl groups further bearing one or more substituents as set forth above.

As used herein, “oxiranylene” or “epoxy” refer to divalent moieties having the structure:

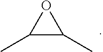

The term “epoxy” also refers to thermosetting epoxide polymers that cure by polymerization and crosslinking when mixed with a catalyzing agent or “hardener,” also referred to as a “curing agent” or “curative.” Epoxies of the present invention include, but are not limited to aliphatic, cycloaliphatic, glycidyl ether, glycidyl ester, glycidyl amine epoxies, and the like, and combinations thereof.

As used herein, “arylene” refers to a divalent aryl moiety. “Substituted arylene” refers to arylene moieties bearing one or more substituents as set forth above.

As used herein, “acyl” refers to alkyl-carbonyl species.

As used herein, the term “oxetane” refers to a compound bearing at least one moiety having the structure:

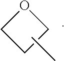

“Imide” as used herein, refers to a functional group having two carbonyl groups bound to a primary amine or ammonia. The general formula of an imide of the invention is:

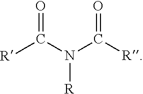

“Polyimides” are polymers of imide-containing monomers. Polyimides are typically linear or cyclic. Non-limiting examples of linear and cyclic (e.g. an aromatic heterocyclic polyimide) polyimides are shown below for illustrative purposes.

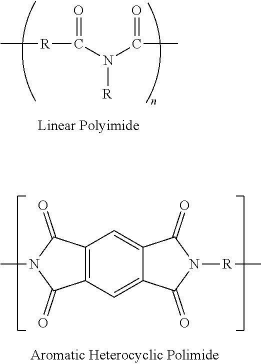

where R is an aromatic, heteroaromatic, aliphatic, or polymeric moiety.

“Maleimide,” as used herein, refers to an N-substituted maleimide having the formula as shown below:

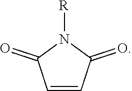

where R is an aromatic, heteroaromatic, aliphatic, or polymeric moiety.

“Bismaleimide” or “BMI”, as used herein, refers to compound in which two imide moieties are linked by a bridge, i.e. a compound a polyimide having the general structure shown below:

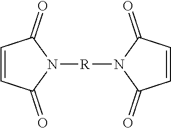

where R is an aromatic, heteroaromatic, aliphatic, or polymeric moiety.

BMIs can cure through an addition rather than a condensation reaction, thus avoiding problems resulting from the formation of volatiles. BMIs can be cured by a vinyl-type polymerization of a pre-polymer terminated with two maleimide groups.

As used herein, the term “acrylate” refers to a compound bearing at least one moiety having the structure:

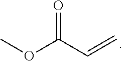

As used herein, the term “acrylamide” refers to a compound bearing at least one moiety having the structure:

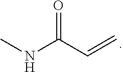

As used herein, the term “methacrylate” refers to a compound bearing at least one moiety having the structure:

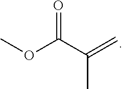

As used herein, the term “methacrylamide” refers to a compound bearing at least one moiety having the structure:

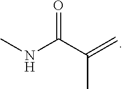

As used herein, “maleate” refers to a compound bearing at least one moiety having the structure:

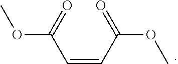

As used herein, the term “acyloxy benzoate” or “phenyl ester” refers to a compound bearing at least one moiety having the structure:

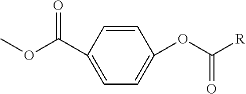

where R is H, lower alkyl, or aryl.

As used herein, the term “citraconimide” refers to a compound bearing at least one moiety having the structure:

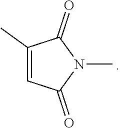

“Itaconimide”, as used herein refers to a compound bearing at least one moiety having the structure:

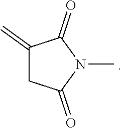

As used herein, “benzoxazine” refers to moieties including the following bicyclic structure:

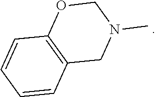

As used herein, the terms “halogen,” “halide,” or “halo” include fluorine, chlorine, bromine, and iodine.

As used herein, the term “vinyl ether” refers to a compound bearing at least one moiety having the structure:

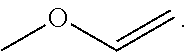

As used herein, the term “vinyl ester” refers to a compound bearing at least one moiety having the structure:

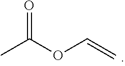

“Allyl” as used herein, refers to refers to a compound bearing at least one moiety having the structure:

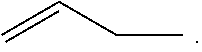

As used herein, “styrenic” and “styrene” refer to a compound bearing at least one moiety having the structure:

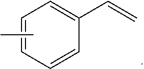

“Fumarate” as used herein, refers to a compound bearing at least one moiety having the structure:

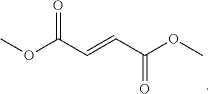

“Propargyl” as used herein, refers to a compound bearing at least one moiety having the structure:

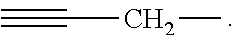

“Cyanate ester” as used herein, refers to a compound bearing at least one moiety having the structure:

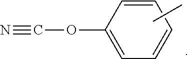

As used herein, “norbornyl” refers to a compound bearing at least one moiety having the structure:

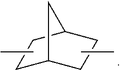

As used herein, “siloxane” refers to any compound containing a Si—O moiety. Siloxanes may be either linear or cyclic. In certain embodiments, siloxanes of the invention include 2 or more repeating units of Si—O. Exemplary cyclic siloxanes include hexamethylcyclotrisiloxane, octamethylcyclotetrasiloxane, decamethylcyclopentasiloxane, dodecamethylcyclohexasiloxane and the like.

As used herein, a “primary amine terminated difunctional siloxane bridging group” refers to a moiety having the structural formula:

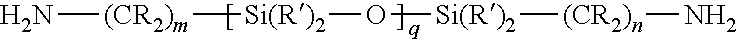

where each R is H or Me, each R′ is independently H, lower alkyl, or aryl; each of m and n is an integer having the value between 1 to about 10, and q is an integer having the value between 1 and 100.

As used herein, the term “free radical initiator” refers to any chemical species which, upon exposure to sufficient energy (e.g., light, heat, or the like), decomposes into parts, which are uncharged, but every one of such part possesses at least one unpaired electron.

As used herein, the term “coupling agent” refers to chemical species that are capable of bonding to a mineral surface and which also contain polymerizably reactive functional group(s) so as to enable interaction with the adhesive composition. Coupling agents thus facilitate linkage of the die-attach paste to the substrate to which it is applied.

“Diamine”, as used herein, refers generally to a compound or mixture of compounds, where each species has 2 amine (—NH₂) groups, such as the following structure:

H₂N—R—NH₂.

“Anhydride” as used herein, refers to a compound bearing at least one moiety having the structure:

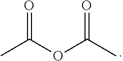

“Dianhydride,” as used herein, refers generally to a compound or mixture of compounds, where each species has 2 anhydride groups.

The term “solvent,” as used herein, refers to a liquid that dissolves a solid, liquid, or gaseous solute, resulting in a solution. “Co-solvent” refers to a second, third, etc. solvent used with a primary solvent.

As used herein, “polar protic solvents” are ones that contain an O—H or N—H bond, while “polar aprotic solvents” do not contain an O—H or N—H bond.

“Glass transition temperature” or “T_{g}”: is used herein to refer to the temperature at which an amorphous solid, such as a polymer, becomes brittle on cooling, or soft on heating. More specifically, it defines a pseudo second order phase transition in which a supercooled melt yields, on cooling, a glassy structure and properties similar to those of crystalline materials e.g. of an isotropic solid material.

“Modulus” or “Young's modulus” as used herein, is a measure of the stiffness of a material. Within the limits of elasticity, modulus is the ratio of the linear stress to the linear strain, which can be determined from the slope of a stress-strain curve created during tensile testing.

The “Coefficient of Thermal Expansion” or “CTE” is a term of art describing a thermodynamic property of a substance. The CTE relates a change in temperature to the change in a material's linear dimensions. As used herein “α₁ CTE” or “α₁” refers to the CTE before the Ts, while “α₂ CTE” refers to the CTE after the T_{g}.

“Thixotropy” as used herein, refers to the property of a material which enables it to stiffen or thicken in a relatively short time upon standing, but upon agitation or manipulation to change to low-viscosity fluid; the longer the fluid undergoes shear stress, the lower its viscosity. Thixotropic materials are therefore gel-like at rest but fluid when agitated and have high static shear strength and low dynamic shear strength.

“Thermogravimetric analysis” or “TGA” refers to a method of testing and analyzing a material to determine changes in weight of a sample that is being heated in relation to change in temperature.

“Decomposition onset” refers to a temperature when the loss of weight in response to the increase of the temperature indicates that the sample is beginning to degrade.

Polyimides with terminal reactive moieties are described in U.S. Pat. Nos. 7,884,174 B2, 7,157,587 B2, and 8,513,375 B2 and are fully disclosed and incorporated herein by reference.

The invention is based on the discovery that certain functionalized polyimide compounds can be cast into thin, flexible films that are suitable for preparing flexible copper clad laminates, when they are synthesized to have a high molecular weight that is greater than 20,000 Daltons. Polyimides with average molecular weights less than 20,000 Daltons produce films that are very brittle and are not suitable for applications where flexibility is needed, such as thin, rollable films.

The invention polyimides are curable; therefore, obviating the use of adhesive layers for the preparation of FCCL. The curable invention polyimide material can be cast from solution to form thin films that are flexible and rollable. The films can be cut to size and placed between copper foils. Once heated during a lamination process, the material cures and adheres to the copper foil acting as a dielectric layer for FCCL

Flexibility and rollability are determined by the polyimide composition (substantially aromatic) and molecular weight (MW). It has been discovered that an average molecular weight of 20,000 Daltons yields a flexible polyimide, as disclosed below in the EXAMPLES, while lower MW leads to brittle polyimides that crack and cannot be formed into malleable films. When mostly aromatic polyimides are synthesized with an average MW of less than 20,000 Daltons, films cast from the polymer are very brittle and neither flexible nor rollable. When the average molecular weight of an aromatic polyimide of the invention is greater than 20,000 Daltons, films cast and dried from a solution of the polyimide in solvent are a flexible and rollable.

In one embodiment, the polyimides of the invention have an average molecular weight at least about 20,000 Daltons, such as at least about 25,000 Daltons at least about 30,000 Daltons, at least about 35,000 Daltons, at least about 40,000 Daltons, at least about 45,000 Daltons or at least about 50,000 Daltons. In other embodiments, the polyimides of the invention have an average molecular weight of about 20,000 to about 50,000 Daltons, about 25,000 to about 50,000 Daltons, about 30,000 to about 50,000 Daltons, about 35,000 to about 50,000 Daltons about 40,000 to about 50,000 Daltons, or about 45,000 to about 50,000 Daltons. An average molecular weight above 25,000 Daltons allows for terminal functionalization that facilitates curing to produce a thermoset.

The invention thus provides compounds having a structure according to Formula I:

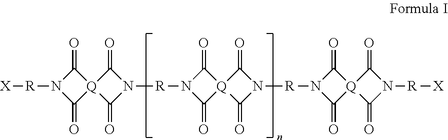

where R is selected from the group consisting of: substituted or unsubstituted aromatic, aliphatic, cycloaliphatic, alkenyl, polyether, polyester, polyamide, heteroaromatic, and siloxane, and combinations thereof; Q is selected from the group consisting of: substituted or unsubstituted aromatic, aliphatic, cycloaliphatic, alkenyl, polyether, polyester, polyamide, heteroaromatic, siloxane, and combinations thereof; X is a curable moiety; and n is 0 or an integer having the value from 1 to 100; and with the proviso that, the average molecular weight of the material is greater than 20,000 Daltons.

The polyimides are functionalized with polymerizable moieties (X), particularly terminal functional groups. The terminal functional group can be, for example maleimide, benzoxazine, citraconimide, itaconimide, acrylate, methacrylate, epoxy, phenol/phenolic, vinyl ether, acrylamide, methacrylamide, free-amine, anhydride or mixtures thereof.

In certain aspects, R is selected from:

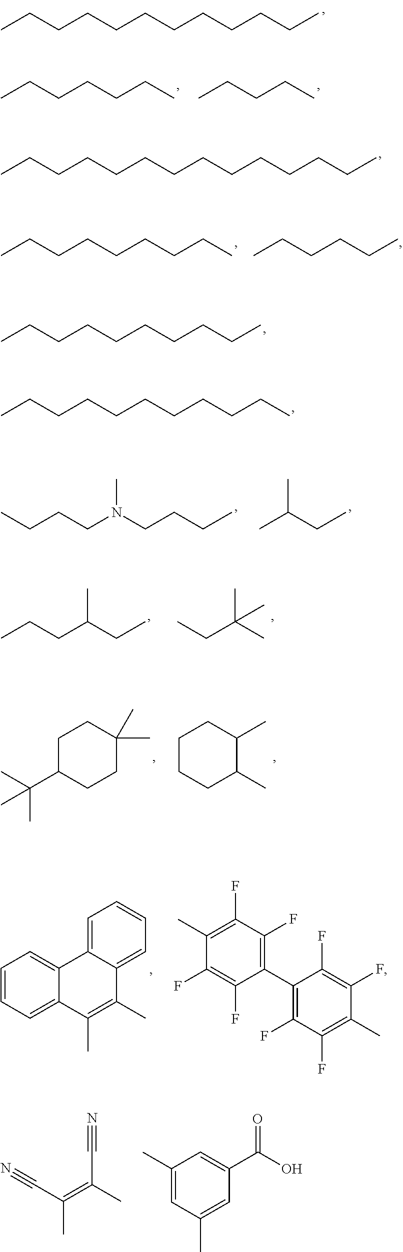

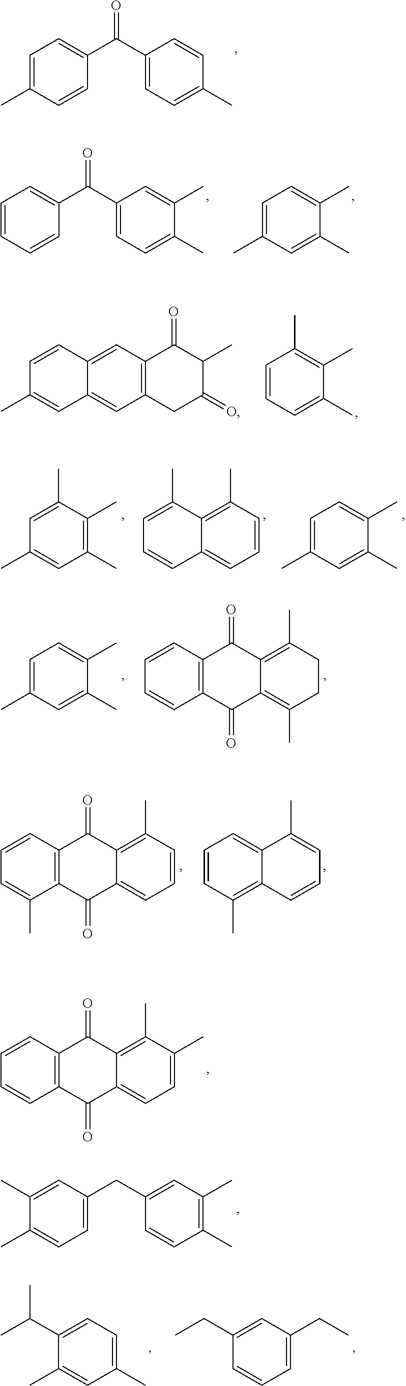

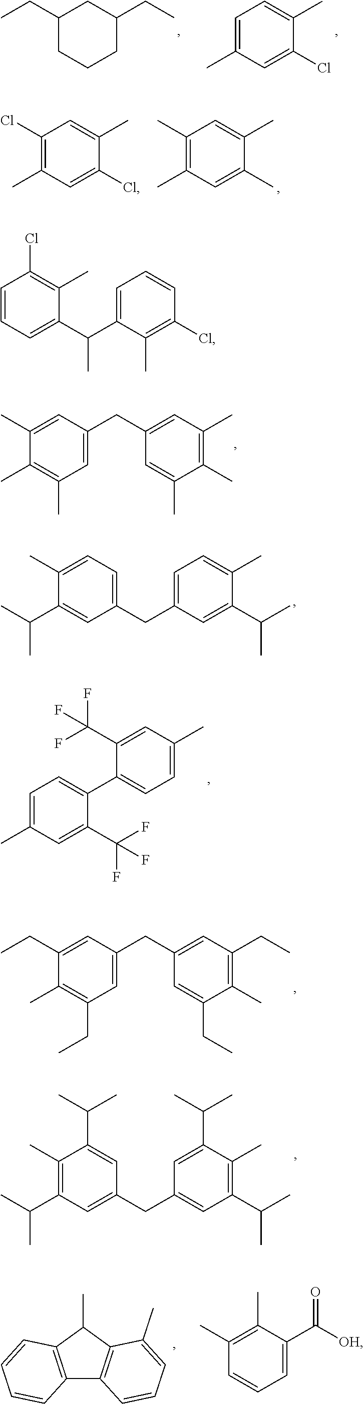

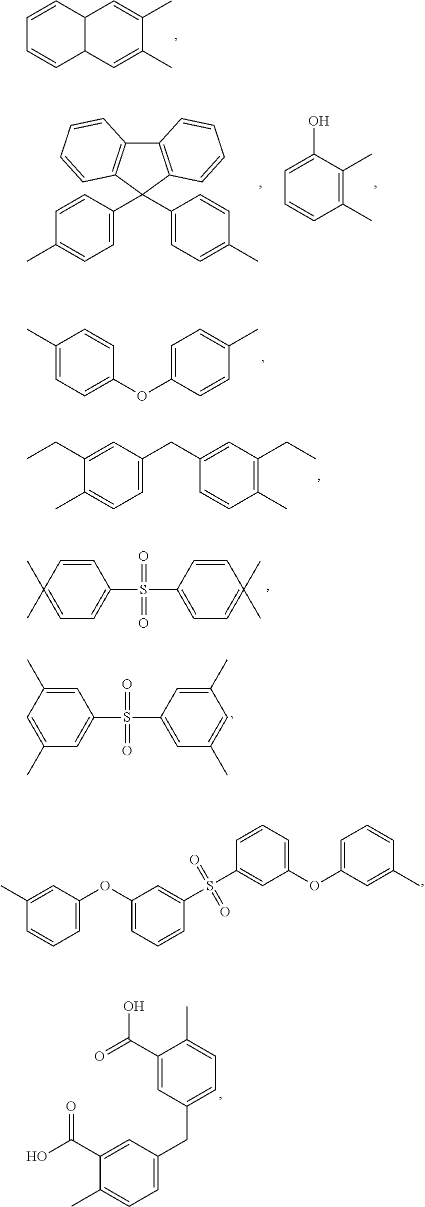

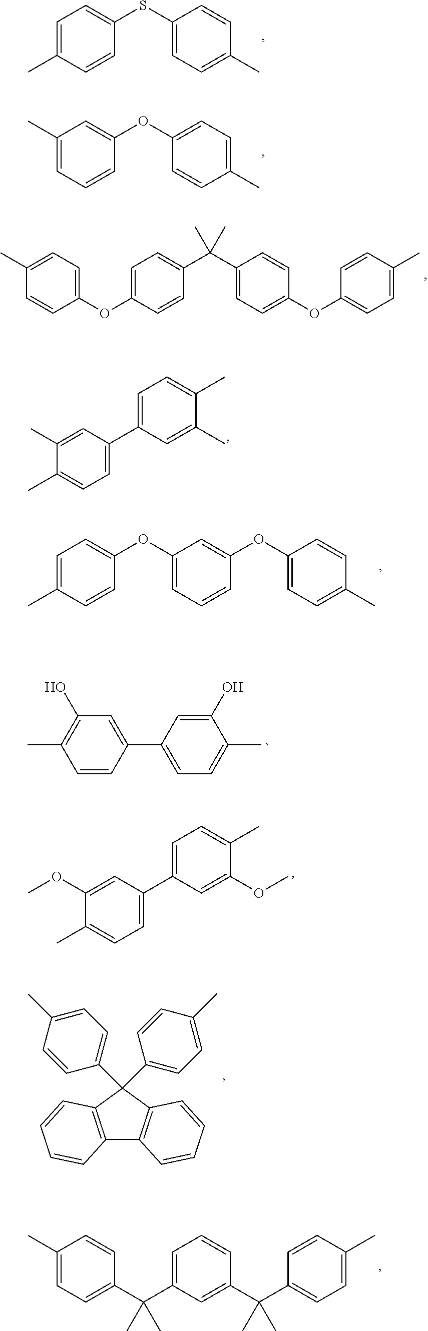

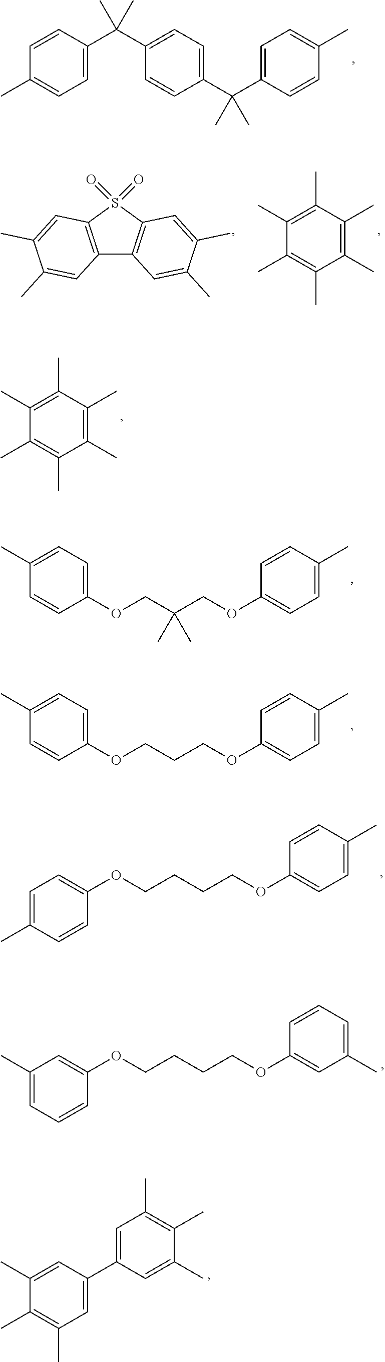

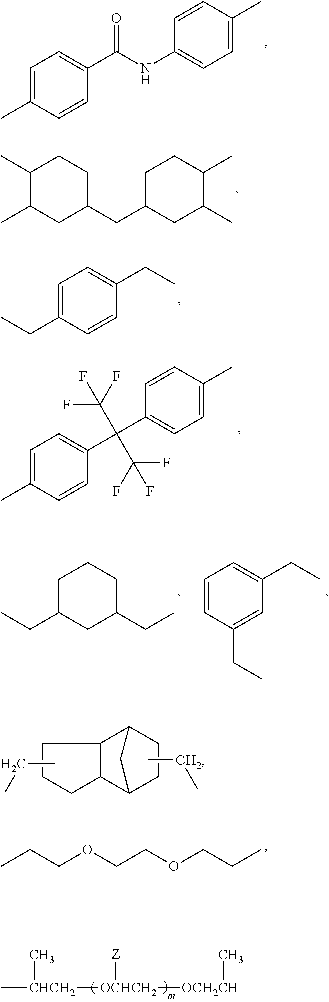

wherein Z is H or Me and m is an integer wherein the average molecular weight between 200 and 800 Daltons, and combinations thereof.

In certain aspects, Q is selected from:

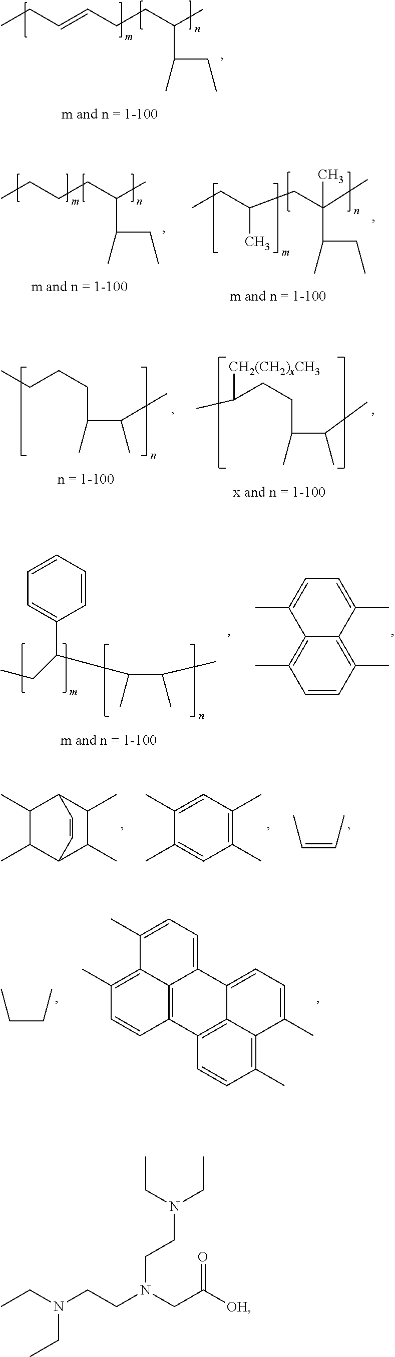

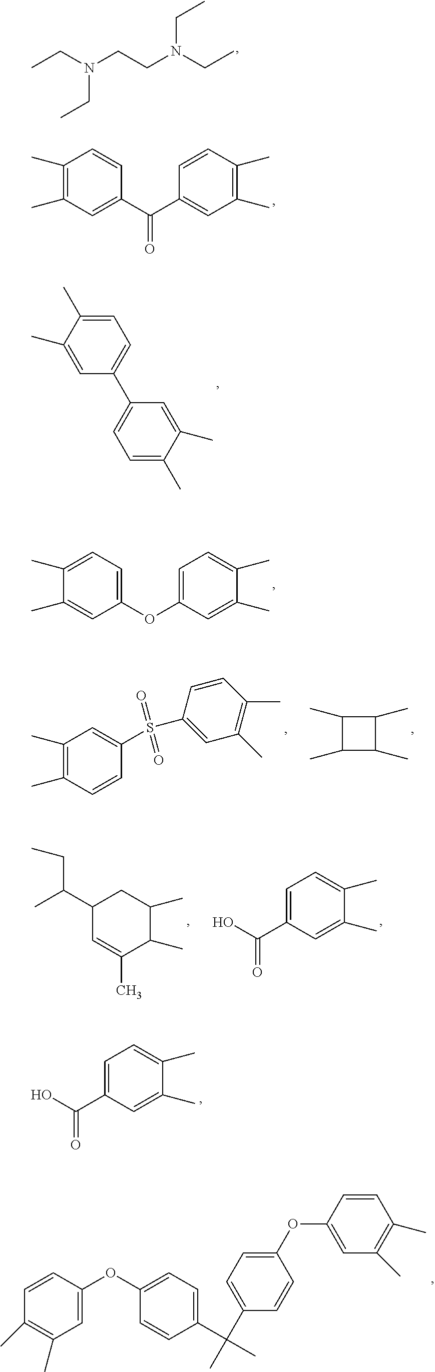

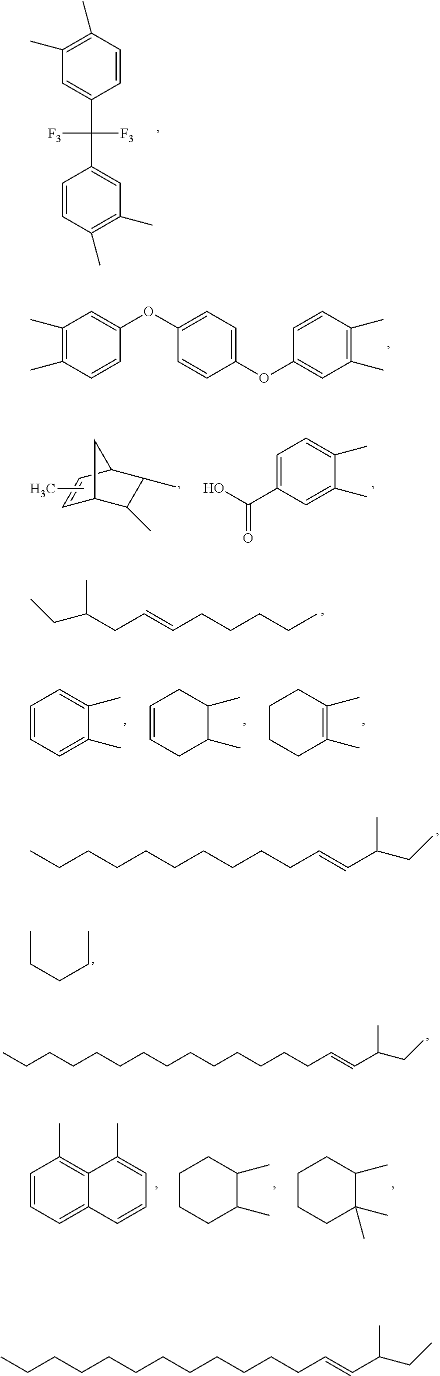

and combinations thereof.

The compounds of Formula I are synthesized according to the process shown in Scheme 1, below:

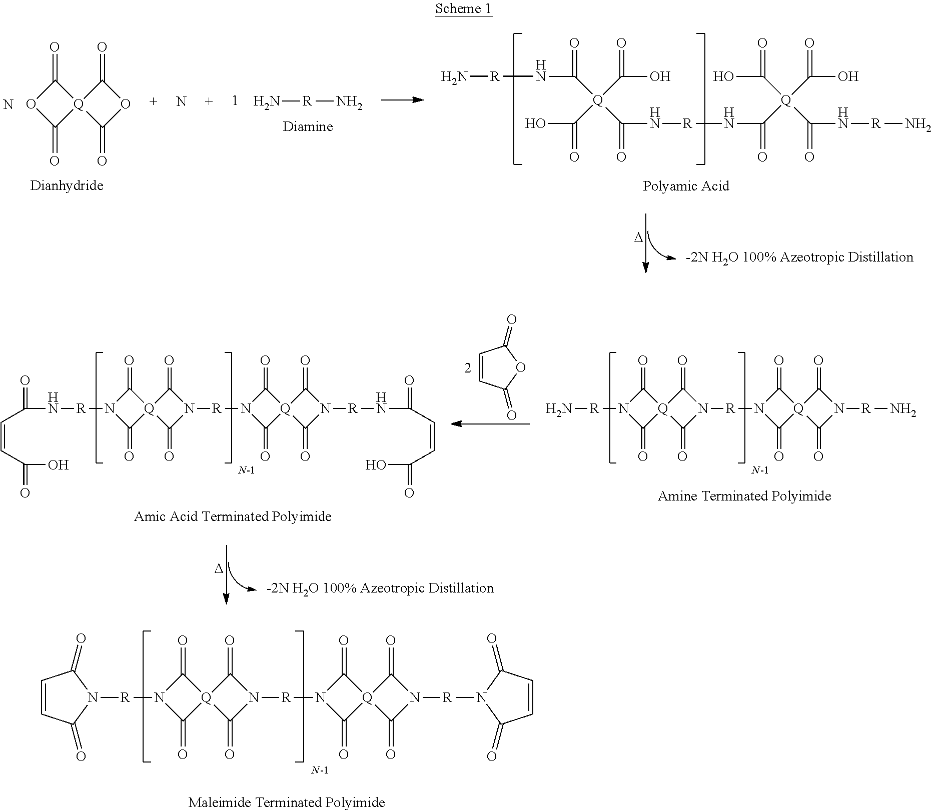

Briefly, method by the process starts with the condensation of one or more diamines with one or more dianhydrides to form a polyamic acid, followed by azeotropic distillation (cyclodehydration) yielding an amine terminated polyimide. Advantageously, this method facilitates accurate monitoring of the reaction by collecting and optionally quantifying the amount of water produced. The reaction is complete when no additional water is produced.

The entire synthesis can be carried out in an appropriate solvent in which the reactants, intermediates and/or product are soluble. The solvents used most often in the synthesis of polyimides are polar aprotic solvents such as; NMP, DMF, DMAC, and DMSO. Advantageously, very high molecular weight polyimides can be produced by adding the dianhydride to a diamine solution in such solvents, and stirring at room temperature for several hours. The polyamic acid intermediate is very soluble polar aprotic solvents. Often an aromatic solvent such as toluene is added to help azeotrope out the water generated in the thermal cyclodehydration reaction to produce the polyimide. A disadvantage of these solvents is that they have very high boiling points, and may need to be washed out of the resin after the reaction is complete. Alternatively, the resin can be left in solution. However, the extremely high boiling point of these solvents make them difficult to remove completely, even from a thin film, without exposure to very high temperature, which may cure the functionalized polyimides prematurely. Furthermore, many end users of the resin do not like to work with polar aprotic solvents due to their toxicity and associated disposal costs.

Preferably, the solvent is anisole. In some cases, one or more reactants has lower solubility in anisole at room temperature. However, the elevated temperature of the reaction during reflux, combined with the removal of the reactants to intermediates formed, allows the dianhydrides and diamines to fully react even with limited solubility.

Thereafter, the amine-terminated polyimides are end-capped with a suitable curable reagent, such as the maleic anhydride illustrated in Scheme 1, which gives maleimide terminal functionalization. Any amine-reactive, curable moiety can be used in this aspect of the process. Suitable amine-reactive reagents will be known to the skilled artisan.

The clear advantage to the methods of the invention is the high degree of imidization that can be achieved by conducting the imidization in a refluxing solvent (e.g. anisole) with azeotropic removal of water that is generated. The end point of the reaction is reached when no more water is produced. This method produces organic soluble functionalized polyimides in an acceptable solvent such as anisole which is easy to remove and process. While the polyimides can be precipitated from the anisole solution, it is not required nor are costly and time-consuming washing steps needed to remove hazardous polar protic solvents.

The physical properties of these maleimide-capped polyimide resins range from low melting solids to viscous liquids, as described in U.S. Pat. Nos. 7,884,174 B2, and 7,157,587 B2. The patents also describe polyimides functionalized with other curable moieties. These compounds are high-performance elastomers for electronics applications due to the inherent properties of the molecules, including hydrophobicity, hydrolysis resistance, low melt viscosities for solids, room temperature liquid state, very high temperature resistance, and the low modulus. Many of these compounds have very low dielectric constants and low dielectric dissipation factors.

Advantageously, maleimides can be polymerized through a variety of methods. Due to the electron-deficient nature of the maleimide double bond, these compounds can undergo free-radical polymerization using standard peroxide initiators. Maleimide compounds also can undergo polymerization via Diels-Alder reactions and ene-reactions. The maleimide double bond also undergoes reaction with thiols, Michael reaction with amines, as well as anionic chain polymerization.

The methods of the present invention permit customization of the reactions the curable polyimides can participate in. Depending on the environment, substrate or down-stream reactions anticipated, the terminal functionalization can be selected accordingly.

One limitation of prior polyimides is brittleness. The present invention overcomes this limitation by controlling the molecular weight of the final products. As described above, the curable polyimides of the invention with molecular weights above 20,000 Daltons are flexible and can be used in applications where rollability is required, such as flexible copper clad laminates and flexible circuitry.

While many polyimides in the art are synthesized under conditions of excess dianhydride leading to polymers with low molecular weight. The polyimides of the present invention are synthesized under conditions of diamine excess in a refluxing solvent that yields polymers >20,000 Daltons. In certain embodiments, the ratio of diamine to dianhydride equivalents is about 1.01:1 to about 1.10:1, such as about 1.02:1 to about 1.09:1; about 1.03:1 to about 1.08:1; about 1.04:1 to about 1.07:1; or about 1.05:1 to about 1.06. In certain aspects of the invention, the equivalent ratio of diamine to dianhydride is about 1.05:1.

### Uses of Curable, High Molecular Weight Polyimides

Copper clad laminates are materials that are made from layers of a polymer dielectric material sandwiched between copper foil, in many cases multi-layers of these materials are laminated together under pressure and heat to produce a composite that can be used to make printed circuit boards.

In order to produce a copper clad laminate from polyimides of the invention, a continuous thin film of the uncured polyimide can be cast. The polyimide can then be dried and wound into giant rolls. The rolls of polyimide are then cut to size and sandwiched between copper foils. Multi-layered material can also be prepared, followed by lamination process under heat and pressure to adhere the copper foil to the polyimide. The heat of lamination polymerizes the functionalized polyimides leading to good adhesion to the copper foil.

We have determined that an average molecular weight 20,000 Daltons allows the polyimides of the invention to be cast into a thin, flexible films, which can be wound into a roll, as described in the Examples below.

In another embodiment of the invention the terminal groups are functionalized with polymerizable moieties. These polymerizable moieties are preferably maleimide, citraconimide, itaconimide, acrylate, methacrylate, epoxy, benzoxazine, phenol, vinyl ether, acrylamide, methacrylamide, amine, anhydride, and so on.

In another embodiment of the invention, alternative solvents have been found that work well in producing the functionalized polyimides. The solvent includes aromatic solvents especially ether functionalized aromatic solvents such as anisole. Anisole does a nice job of dissolving the polyimides as well as being able to handle the polyamic acid intermediate. Anisole is relatively unreactive and seems to produce polyimides with minimum color, whereas the polar aprotic solvents seem to produce polyimides that are very dark.

In certain embodiments, the invention synthesis is carried by adding the diamine components to reactor with anisole, followed by the addition of the dianhydride. Stirring at room temperature as well as having nearly equivalent amounts of diamine and dianhydride (or slight diamine excess as described above), produces the highest molecular weights. Often the polyamic acid intermediate is not highly soluble in solvents used in the practice of the invention. However, as the material is slowly heated, the reagents and intermediates dissolve, and water is observed being produced by the cyclodehydration reaction. After one to two hours of reflux, all of the water has been removed (and can be quantitated to determine the extent of the reaction) from the reaction and the fully imidized polymer is formed. At this point to place the curable moiety at the terminal positions then the amino-terminal groups are reacted with maleic anhydride, citraconic anhydride to itaconic anhydride to make the corresponding maleimide, citraconimide or itaconimide derivatives. The terminal moiety is closed via the cyclodehydration reaction with the aid of an acid catalyst. In order to have a product that is easily worked-up typically the acid catalyst used is a polymer bound sulfonic acid (Amberlyst® 36 resin). The beads of catalyst are simply filtered out of solution after the reaction is complete making the workup as simple as possible.

U.S. Pat. No. 7,884,174 B2, U.S. Pat. No. 7,157,587 B2, and U.S. Pat. No. 8,513,375 B2 (Mizori et al) and incorporated herein by reference discuss the synthesis and properties of imide-extended maleimide. The discovery of imide extended maleimide compounds in the liquid form or as low melting solids has enabled the formulator to use these compounds as additives in a variety of formulations to impart toughness, high temperature resistance, and hydrolysis resistance.

A wide variety of diamines are contemplated for use in the practice of the invention, such as for example, 1,10-diaminodecane; 1,12-diaminododecane; dimer diamine; hydrogenated dimer diamine; 1,2-diamino-2-methylpropane; 1,2-diaminocyclohexane; 1,2-diaminopropane; 1,3-diaminopropane; 1,4-diaminobutane; 1,5-diaminopentane; 1,7-diaminoheptane; 1,8-diaminomenthane; 1,8-diaminooctane; 1,9-diaminononane; 3,3′-diamino-N-methyldipropylamine; diaminomaleonitrile; 1,3-diaminopentane; 9,10-diaminophenanthrene; 4,4′-diaminooctafluorobiphenyl; 3,5-diaminobenzoic acid; 3,7-diamino-2-methoxyfluorene; 4,4′-diaminobenzophenone; 3,4-diaminobenzophenone; 3,4-diaminotoluene; 2,6-diaminoanthroquinone; 2,6-diaminotoluene; 2,3-diaminotoluene; 1,8-diaminonaphthalene; 2,4-diaminotoluene; 2,5-diaminotoluene; 1,4-diaminoanthroquinone; 1,5-diaminoanthroquinone; 1,5-diaminonaphthalene; 1,2-diaminoanthroquinone; 2,4-cumenediamine; 1,3-bisaminomethylbenzene; 1,3-bisaminomethylcyclohexane; 2-chloro-1,4-diaminobenzene; 1,4-diamino-2,5-dichlorobenzene; 1,4-diamino-2,5-dimethylbenzene; 4,4′-diamino-2,2′-bistrifluoromethylbiphenyl; bis(amino-3-chlorophenyl)ethane; bis(4-amino-3,5-dimethylphenyl)methane; bis(4-amino-3,5-diisopropylphenyl)methane; bis(4-amino-3,5-methyl-isopropylphenyl)methane; bis(4-amino-3,5-diethylphenyl)methane; bis(4-amino-3-ethylphenyl)methane; diaminofluorene; 4,4′-(9-Fluorenylidene)dianiline; diaminobenzoic acid; 2,3-diaminonaphthalene; 2,3-diaminophenol; −5-methylphenyl)methane; bis(4-amino-3-methylphenyl)methane; bis(4-amino-3-ethylphenyl)methane; 4,4′-diaminophenylsulfone; 3,3′-diaminophenylsulfone; 2,2-bis(4-(4-aminophenoxy)phenyl)sulfone; 2,2-bis(4-(3-aminophenoxy)phenyl)sulfone; 4,4′-oxydianiline; 4,4′-diaminodiphenyl sulfide; 3,4′-oxydianiline; 2,2-bis(4-(4-aminophenoxy)phenyl)propane; 1,3-bis(4-aminophenoxy)benzene; 4,4′-bis(4-aminophenoxy)biphenyl; 4,4′-diamino-3,3′-dihydroxybiphenyl; 4,4′-diamino-3,3′-dimethylbiphenyl; 4,4′-diamino-3,3′-dimethoxybiphenyl; Bisaniline M; Bisaniline P; 9,9-bis(4-aminophenyl)fluorene; o-tolidine sulfone; methylene bis(anthranilic acid); 1,3-bis(4-aminophenoxy)-2,2-dimethylpropane; 1,3-bis(4-aminophenoxy)propane; 1,4-bis(4-aminophenoxy)butane; 1,5-bis(4-aminophenoxy)butane; 2,3,5,6-tetramethyl-1,4-phenylenediamine; 3,3′,5,5′-tetramehylbenzidine; 4,4′-diaminobenzanilide; 2,2-bis(4-aminophenyl)hexafluoropropane; polyoxyalkylenediamines; 1,3-cyclohexanebis(methylamine); m-xylylenediamine; p-xylylenediamine; bis(4-amino-3-methylcyclohexyl)methane; 1,2-bis(2-aminoethoxy)ethane; 3(4),8(9)-bis(aminomethyl)tricyclo(5.2.1.0²⁶)decane; and any other diamines or polyamines.

A wide variety of anhydrides are contemplated for use in the practice of the invention, such as, for example, polybutadiene-graft-maleic anhydride; polyethylene-graft-maleic anhydride; polyethylene-alt-maleic anhydride; polymaleic anhydride-alt-1-octadecene; polypropylene-graft-maleic anhydride; poly(styrene-co-maleic anhydride); pyromellitic dianhydride; maleic anhydride, succinic anhydride; 1,2,3,4-cyclobutanetetracarboxylic dianhydride; 1,4,5,8-naphthalenetetracarboxylic dianhydride; 3,4,9,10-perylenentetracarboxylic dianhydride; bicyclo(2.2.2)oct-7-ene-2,3,5,6-tetracarboxylic dianhydride; diethylenetriaminepentaacetic dianhydride; ethylenediaminetetraacetic dianhydride; 3,3′,4,4′-benzophenone tetracarboxylic dianhydride; 3,3′,4,4′-biphenyl tetracarboxylic dianhydride; 4,4′-oxydiphthalic anhydride; 3,3′,4,4′-diphenylsulfone tetracarboxylic dianhydride; 2,2′-bis(3,4-dicarboxyphenyl)hexafluoropropane dianhydride; 4,4′-bisphenol A diphthalic anhydride; 5-(2,5-dioxytetrahydro)-3-methyl-3-cyclohexene-1,2-dicarboxylic anhydride; ethylene glycol bis(trimellitic anhydride); hydroquinone diphthalic anhydride; allyl nadic anhydride; 2-octen-1-ylsuccinic anhydride; phthalic anhydride; 1,2,3,6-tetrahydrophthalic anhydride; 3,4,5,6-tetrahydrophthalic anhydride; 1,8-naphthalic anhydride; glutaric anhydride; dodecenylsuccinic anhydride; hexadecenylsuccinic anhydride; hexahydrophthalic anhydride; methylhexahydrophthalic anhydride; tetradecenylsuccinic anhydride; and the like. In the use of the mono-anhydrides the chain would be terminated.

The polymerizable moiety that terminates the polymers is represented by X in Formula I1. The polymerizable moiety can be maleimide or substituted maleimide; an acrylamide or methacrylamide; benzoxazine; or it can be a free amine.

The terminal groups in the polyimide can also be changed to other curable moieties, by using excess anhydride to make the polyimide an anhydride terminated oligomer is obtained, which in itself can be useful as a curative for epoxy compounds. Anhydride terminated polymers can be reacted with an aminophenol, this would produce a phenolic terminated polyimide that could subsequently be transformed into a glycidyl ether, a benzoxazine, or a cyanate ester.

The reaction of a terminal anhydride with an amino alcohol will provide an alcohol terminated polyimide, that can subsequently be transformed into an acrylate or methacrylate, a glycidyl ester, or a vinyl ester.

The high molecular weight curable polyimides of the invention are contemplated for use as a dielectric layer between copper foils, such as in a flexible copper clad laminate.

The invention compositions are contemplated for use in high frequency electronics applications, such as CCL, FCCL, radar antennae, capacitors, wire coatings and insulators.

Also contemplated for use is the addition of fillers to help enhance the properties of the material. Non-limiting examples of fillers that may be added to the compositions of the invention include silica, perfluorinated hydrocarbons (e.g. Teflon™), boron nitride, polyhedral oligomeric silsesquioxane (POSS), carbon black, graphite, carbon nanotubes, silver, copper, and a metal alloys.

Silica can be added to reduce the Df as well as reduce the CTE of the cured material. The combination of silica plus perfluorotetraethylene (Teflon™), is very effective in reducing the Df of cured polyimides.

The addition of alumina to composition does lower the Df of the material but raises the Dk, which is very useful in capacitor applications.

The invention formulations may contain reactive species as well, which can be in solid form or as reactive diluents. Various bismaleimide resins, benzoxazine resins, cyanate ester resins, phenolic resins, carboxyl resins, polyphenylene oxide (PPO) and polyphenylene ether (PPE), allylic resins, vinyl ethers, various acrylics and epoxy resins can be added to the formulations to obtain higher T_{g}, lower CTE also help provide tack for increased adhesion to various surfaces.

In addition, various coupling agents and adhesion promoters may be necessary to obtain adhesion of the said polyimides to various surfaces, typically enhancing the adhesion of the polymeric material to an inorganic substrate. The coupling agents and adhesion promoters contemplated for use in the practice of the invention include but are not limited to the following: silane coupling agents, titanium coupling agents, zirconium coupling agents, boranes, reactive anhydrides, salts of fatty acids and so on.

In some cases, fire retardants may be necessary to make the product non-flammable. The industry standard is UL94 rating system and a VO flammability rating is desired in many industrial applications. The fire retardants contemplated for use in the practice of the invention include the following non-limiting examples: Various brominated compounds; various metal hydroxides (antimony hydroxide, aluminum hydroxide, magnesium hydroxide); Nitrogen based melamine compounds; and most valuable and readily used phosphorous type flame retardants.

Catalyst may be used to increase the rate of polymerization of the invention compounds. These catalysts include but are not limited to free-radical generators such as organic peroxides; anionic initiators such as imidazoles; cationic initiators such as Lewis acids, and carbenium ion salts.

### Prepregs, Copper-Clad Laminates and Printed Circuit Boards

The present invention also provides compositions and methods for making prepregs (reinforcement fiber pre-impregnated with a resin), copper clad laminates and printed circuit boards. Also provided are prepregs, copper-clad laminates and printed circuit boards comprising polyimides of the invention.

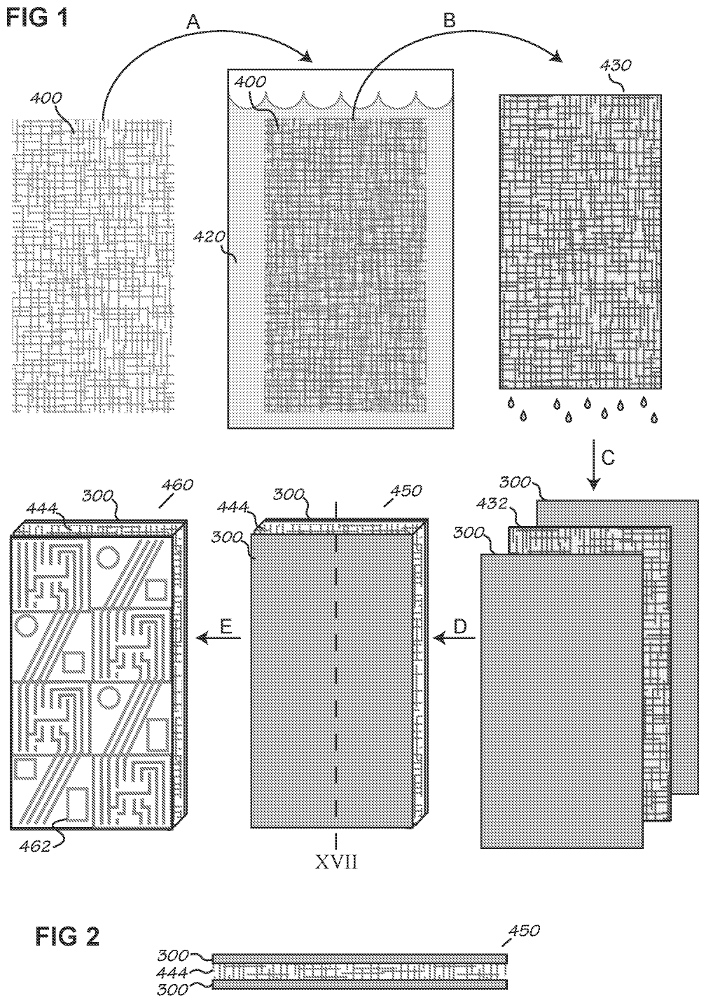

The process for preparing prepregs, copper clad laminates and printed circuit boards is illustrated in FIG. 1. Steps in the process are indicate by arrows. The process begins with a reinforcing fiber 400 such as, fiberglass or carbon fiber. The fiber can be in the form of a woven or unwoven fabric, or single strands of fiber that will be held together by the polymer. The fiber 400 is immersed in a liquid formulation 420 containing an uncured polyimide compound or composition described herein (step A), thereby impregnating the fiber with the polyimide formulation to form a prepreg. The wet prepreg 430 is then drained and dried to remove excess solvent (step B). Conveniently, the dried prepreg 432 can then be stored until needed.

The dried prepreg will typically be coated on one or both side with a layer of copper to form a copper-clad laminate (CCL). The copper can be applied by electroplating or by laminating thin copper foil to the prepreg. FIG. 1 illustrates preparation of a double-sided copper-clad laminate using copper foil 300. Thus, in step C, the dried prepreg 432 is assembled in a sandwich fashion with a sheet of copper foil 300 on either side. Optionally, layers of adhesive can be interleaved between the foil to increase adhesion (not shown). This is likely unnecessary because polyimides of the invention have strong adhesive properties. In some embodiments, adhesion promoters can be added to formulation 420 to increase bonding of the foil to the prepreg. In step D, the foil 300 is laminated to the prepreg 432 using heat and pressure. Advantageously, polyimides of the invention can be cured using heat. FIG. 2 shows a cross section of CCL 450 having a central core of fiber-reinforced, cured polyimide 444, laminated to copper foil 300 on each side.

Circuit patterns 462 can then be formed on either or both sides (double-sided CCL) of the CCL 450 by photolithography to from a printed circuit board (PCB). 460. The resulting PCB exhibits the high structural strength and very high thermo-oxidative resistance necessary for contemporary electronics applications.

### Flexible Copper-Clad Laminates

The compounds and compositions of the invention are useful in any application that requires high temperature stability, adhesion and flexibility. In particular, flexible copper clad laminates (FCCLs) are increasingly used in electronics as they can provide the ultrathin profile demanded by increasing miniaturization. Moreover, circuitry is becoming prevalent in non-traditional situations, such as clothing, where the ability to conform to a three-dimensional shape other than a flat board is required.

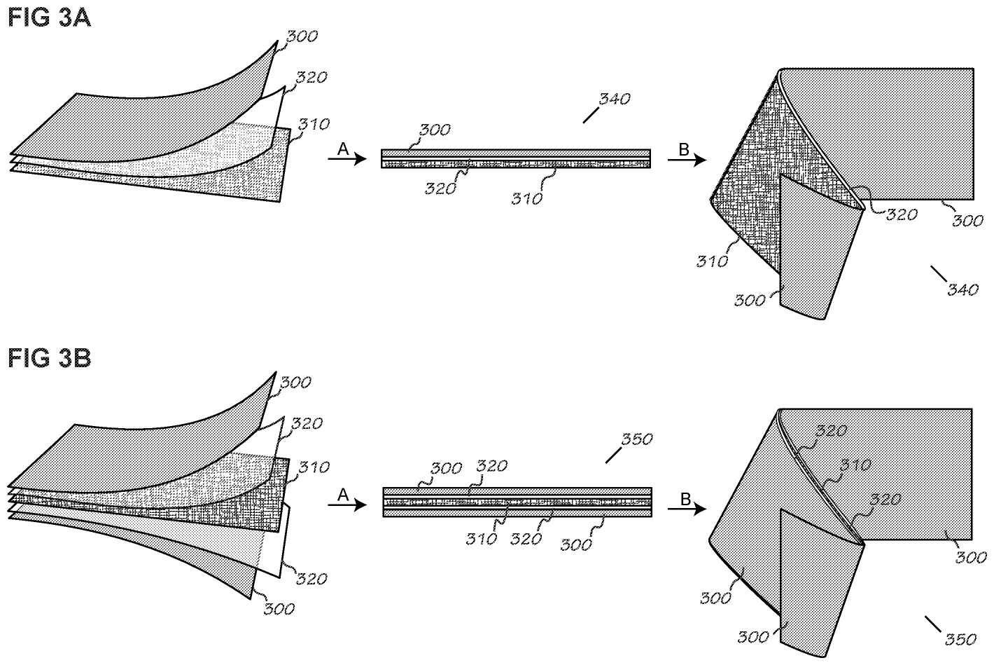

A process of forming FCCLs according to one embodiment of the invention is illustrated in FIGS. 3A and 3B for single- and double-sided FCCLs, respectively. The process is similar to preparing a prepreg-based CCL but is much thinner and lacks the rigidity of a prepreg. A thin and flexible film of polyimide polymer 310 prepared as described herein, is assembled with an adhesive layer 320 and copper foil 300 (FIG. 3A). The assembly is then laminated (step A) to form a single-sided copper clad laminate 340. The FCCL can then be rolled, bent or formed as needed (step B), while providing the basis for thin, flexible circuitry that can be used in consumer electronics, clothing and other goods.

Double-sided FCCL production according to one embodiment of the invention, is illustrated in FIG. 3B. This process is identical to that illustrated in FIG. 3A, except that the adhesive layer 320 and copper foil 300 are placed on both sides of polymer film 310 to form a 5-layer assembly, which is then laminated (step A) to form a double-sided FCCL 350.

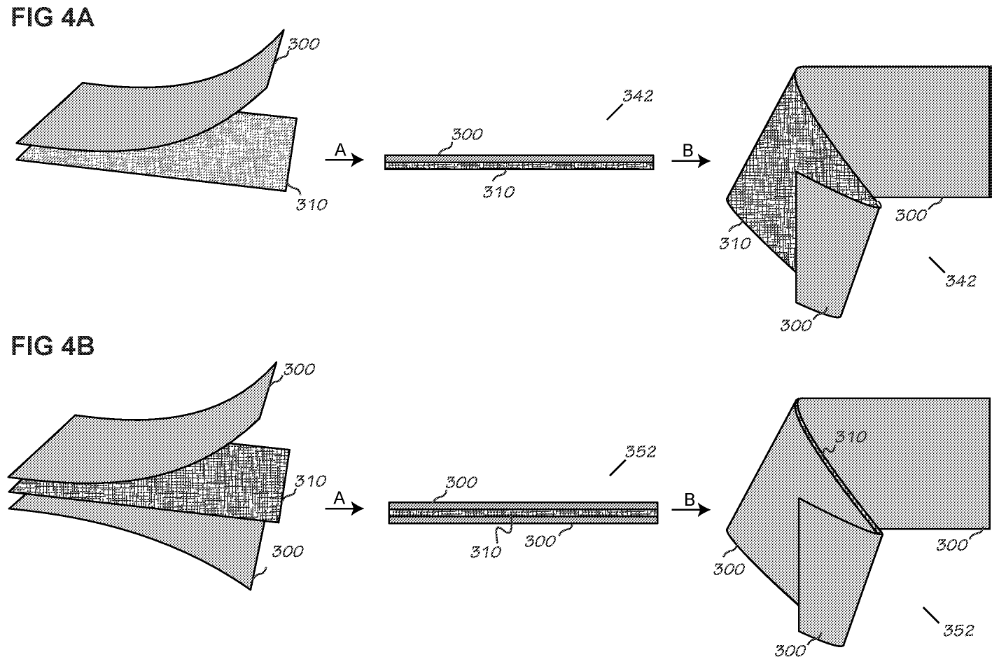

In another embodiment of the invention, adhesiveless processes for producing FCCL are provided as shown in FIGS. 4A and 4B. Single-sided FCCL (FIG. 4A) is prepared by contacting copper foil 300 with one side of a polyimide film 310 prepared as described herein. The film is then heat-cured (step A), onto the foil to form an adhesiveless FCCL 342, which is thinner and more flexible than FCCL that includes an extra layer (i.e., the adhesive layer). The single-sided, adhesiveless FCCL 342 can be rolled, bent, or formed into a desired shape before (step B) or after patterning (not shown).

Double-sided, adhesiveless FCCL can be prepared (FIG. 4B) in the same manner as the single-sided product, except that both sides of film 310 are contacted with foil 300 prior to curing (step B). The double-sided adhesiveless FCCL 352 according to this embodiment of the invention can similarly be rolled, shaped, and formed (step B).

In yet another FCCL embodiment of the invention eliminates the step of forming a polymer film prior to assembly. Instead, a liquid formulation of the polymer is applied directly to the copper foil. Application can be by any method known in the art, such as by pouring, dropping, brushing, rolling or spraying, followed by drying and heat-curing. To prepare a double sided FCCL according to this embodiment of the invention, polymer-coated foil is prepared, dried and then a second foil is contacted on the polymer side of the foil prior to curing.

Application of circuit traces to FCCL can be performed using standard photolithography processes developed for patterning printed circuit boards.

### EXAMPLES

### Materials and Method

### Dynamic Mechanical Analysis (DMA)

Polymer formulations were prepared in a suitable solvent (e.g. anisole) with <5% dicumyl peroxide (Sigma-Aldrich, St. Louis Mo.), and 500 ppm inhibitor mix (Designer Molecules, Inc.; Cat. No. A619730; weight % p-Benzoquinone and 70 weight % 2,6-di-tert-butyl-4-methylphenol) and dispensed into a to 5 inch×5 inch stainless steel mold. The mixture was then vacuum degassing and the solvent (e.g. anisole) was allowed to slowly evaporate at 100° C. for ˜16 hours in an oven. The oven temperature was then ramped to 180° C. and hold for 1 hour for curing. Then the oven temperature was ramp to 200° C. and h1ld for 1 hour before cooling to room temperature. The resulting film (400-800 μm) was then released from mold and cut into strips (˜2 inch×˜7.5 mm) for measurement.

The strips were analyzed on a Rheometrics Solids Analyzer (RSA ii) (Rheometric Scientific Inc.; Piscataway. N.J.) with a temperature ramp from 25 to 250° C. at a rate of 5° C./min under forced air using the Dynamic Temperature Ramp type test with a frequency of 6.28 rad/s. The autotension sensitivity was 1.0 g with max autotension displacement of 3.0 mm and max autotension rate of 0.01 mm/s. During the test, maximum allowed Force was 900.0×g and min allowed force is 3.0×g. Storage modulus and loss modulus temperature were plotted against and temperature. The maximum loss modulus value found was defined as the glass transition (T_{g}).

### Coefficient of Thermal Expansion (CTE)

Formulations were prepared as above for DMA. Samples sufficient to give a 0.2 mm to 10 mm thick film were dried at 100° C. for 2 hours to overnight and cured for 1-2 hours at ≃180° C. to ≃250° C.

Hitachi TMA7100 was used for CTE measurement. The film was placed on the top of a sample holder (disk type quartz) and move down quartz testing probe was lowered onto top of the sample to measure sample thickness. The temperature ramped from 25° C. to 250° C. at a 5° C./min, load 10 mN to measure expansion/compression. CTE was calculated as the slope of length change verses temperature change in ppm/° C. α1 CTE and α2 CTE are calculated based on T_{g}.

### Thermalgravimetric Analysis (TGA)

Thermalgravimetric analysis measurements were performed on an TGA-50 Analyzer (Shimadzu Corporation; Kyoto, Japan) under an air flow of 40 mL/min with heating rate of 5° C./min to or 10° C./min. The sample mass lost versus temperature change was recorded and the decomposition temperature was defined at the temperature at which the sample lost 5% of its original mass.

### Tensile Strength and Percent Elongation

Samples were dried to remove solvent at 100° C. for 2 hours to overnight and cured for 1-2 hours at 180° C.˜250° C. in a metal mold to obtain thin films. Test strip film dimension for test was 6 inch×0.5 inch×0.25 inch; measurement length 4.5 inches.

The tensile strength and percent elongation were measure using an Instron 4301 Compression Tension Tensile Tester. Tensile strength was calculated as the ratio of load verses sample cross-section area (width×thickness). Percent elongation was calculated as the ratio of original length of sample (4.5 inch) verses length at break point.

### Permittivity/Dielectric Constant (Dk) and Loss Tangent/Dielectric Dissipation Factor (D)

Formulations were prepared as above for DMA, except that a 2 inch×2 inch film was cut for analysis.

Dk and Df measurements were carried out by National Technical Systems (Anaheim, Calif., USA) with IPC TM-650 2.5.5.9 as the test procedure. The samples were placed in a conditioning cabinet at 23±2° C. and 50 f 5% relative humidity for 24 hours prior to testing, which was performed at measured conditions of 22.2° C. and 49.7% relative humidity. One sweep of the impedance material analyzer was performed with an oscillatory voltage of 500 mV at 1.5 GHz and the sweep was performed between 99.5% and 100.5% of the desired value (1.4925 GHz and 1.5075 GHz).

### Flammability

Five specimens 5″×½″ (12.7 cm×1.27 cm)×(0.3 mm thickness) of each material were flame ignited, with dry absorbent surgical cotton located 300 mm below the test specimen (drip test for flaming particles) and rated according the specifications summarized in Table 1 below.

TABLE 1
UL94 Standard Flammability Ratings

| Classification | Test |
|---|---|
| HB | slow burning on a horizontal specimen; burning rate <76 mm/min for |
| | thickness <3 mm or burning stops before 100 mm |
| V-2 | burning stops within 30 seconds on a vertical specimen; drips of |
| | flaming particles are allowed. |
| V-1 | burning stops within 30 seconds on a vertical specimen; drips of |
| | particles allowed as long as they are not inflamed. |
| V-0 | burning stops within 10 seconds on a vertical specimen; drips of |
| | particles allowed as long as they are not inflamed |
| 5VB | burning stops within 60 seconds on a vertical specimen; no drips |
| | allowed; plaque specimens may develop a hole. |
| 5VA | burning stops within 60 seconds on a vertical specimen; no drips |
| | allowed; plaque specimens may not develop a hole |

### Gel Permeation Chromatography

Gel permeation chromatography analysis of polymer molecular weight was carried out on an Ultimate 3000 HPLC instrument (Thermo Scientific; Carlsbad, Calif.) using tetrahydrofuran (THF) as eluent solvent and polystyrene standards as reference for molecular weight (MW) calculation based on the retention time of the polymer samples compared to a standard curve. The standards used had MWs of: 96,000; 77,100; 58,900; 35,400; 25,700; 12,500; 9,880; 6,140; 1,920; 953; 725; 570; 360; and 162. UV-vis detecting mode was applied at wavelength 220 nm and 10 mg/mL polymer in THF solution were used for testing.

### Spin Coating and Photolithography

A silicon wafer was secured on the middle of a spin coater and spun at low rpm (550 rpm) while dropping material on rotating wafer surface over approximately 5-10 seconds. The speed was increased to 1,150 rpm and spin for 15 seconds. The coated wafer was dried in an oven at 100° C. for 5-15 min

A photomask was placed on the coated wafer and exposed to UV (I-line, 365 nm) for 50 sec to achieve 500 mJ to cure exposed area. Film thickness was measured post-UV-cure, using a surface profiler.

The film was developed in cyclopentanone or propylene glycol methyl ether acetate (PGMEA) and tetramethlyammonium hydroxide (TMAH) to remove uncured areas of film (negative type photolithography).

Films were air dried post development and film thickness measured to calculate film thickness loss due to development. Film thickness was again measured following curing at 100° C. for 1 hour.

### Chemicals

Unless another supplier is indicated, chemicals were purchased from TCI America, Portland Oreg.

### Example 1: Synthesis of Maleimide-Terminated High MW Polyimide, Compound 1

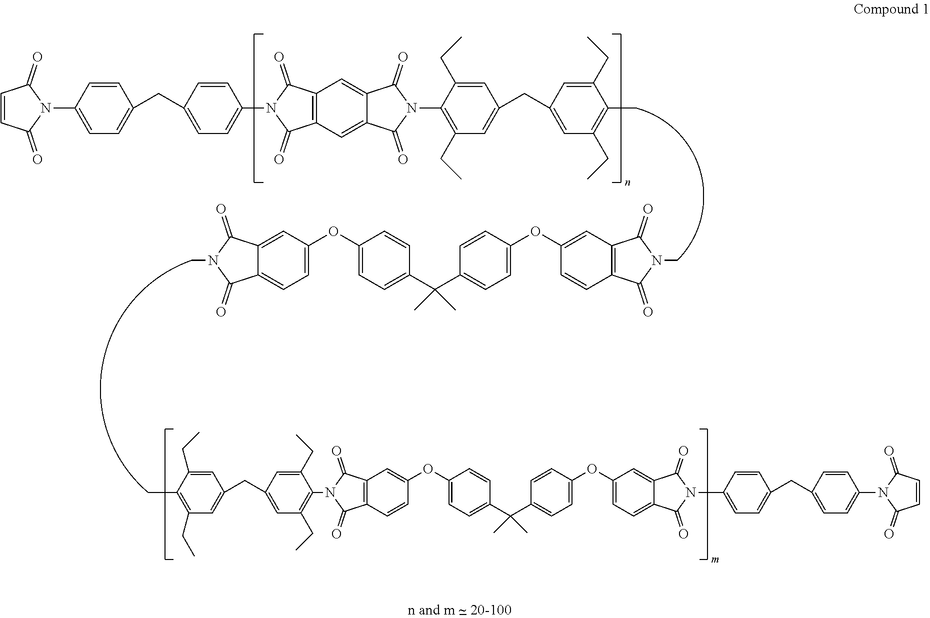

A 3 L reactor was charged with 0.90 mol (279.3 g) of 4,4′-methylenebis(2,6-diethylaniline) (Millipore Sigma; Burlington Mass.) along with 800 g of dimethylformamide (Gallade Chemicals; Escondido Calif.) and 800 g of xylenes (Gallade Chemicals). The solution was stirred while a mixture of 0.60 mol (312.0 g) of bisphenol-A-dianhydride (Millipore Sigma) and 0.40 mol (87.3 g) of pyromellitic dianhydride (Millipore Sigma) was added to the reactor. The mixture was stirred to form a dark solution, followed by heating to about 135° C. to obtain reflux, during which the water produced during the imidization reaction was collected in a Dean-Stark trap. After approximately 3° hours, the reaction was complete, thereby producing an anhydride-terminated polyimide as no further water was generated. The solution was cooled to under 100° C., and quickly 0.15 mol (29.7 g) 4,4′-methylenedianiline (Millipore Sigma) was added to the reactor. The solution was heated to reflux for another 2 hours and the water was removed to produce an amine-terminated polyimide. The solution was cooled to room temperature, followed by the addition of 0.12 mol (11.8 g; 20% excess) maleic anhydride, (Millipore Sigma) followed by the addition of 10.0 g of Amberlyst® 36 acidic ion exchange resin (Dow Chemical; Midland, Mich.). The mixture was again heated to reflux for 3 hours to produce a maleimide-terminated polyimide.

The maleimide-terminated polyimide product was isolated according to the following procedure: The mixture was filtered through a polyester fabric to remove the Amberlyst® 36 resin beads. The solution was reduced to about 40% solids by rotary evaporation, at which point it was sprayed into a tank of stirred methanol (˜10 L) to precipitate the polymer product. The precipitated solid was filtered using a large Buchner funnel and rinsed with additional methanol. The filter cake was allowed to dry sufficiently while stirring on the funnel. The solid was then poured into trays and slowly dried overnight in a recirculating oven as the temperature was slowly increased to about 150° C., to produce 634 g (93.5% of theoretical yield) of a white powder.

Characterization of Product: ¹H NMR (CDCl₃) δ 1.13 (m, 14H), 1.76 (s, 5H), 2.45 (m, 3H), 7.09 (m, 4H), 7.35 (m, 8H), 7.90 (m, 2H), 8.54 (s, 1H). Fourier Transform Infrared Spectroscopy (FTIR) vₘₐₓ 2960, 1721, 1600, 1369, 1232, 846.

TGA analysis of the dried powder showed about 1.5% weight loss at 400° C. and an onset of decomposition of about 504° C.

Gel Permeation Chromatography (GPC) of the material showed an average molecular weight (MW) of ˜22,500 Daltons, with a Polydispersity Index (PDI) of 1.18.

Film Preparation. In a plastic cup, 10.0 g of the dried powder was dissolved in 30 g of toluene (Gallade Chemical) to make a 25% solids solution. To the solution was also added 1000 ppm of butylated hydroxytoluene (BHT) (Millipore Sigma) and 0.2 g of dicumyl peroxide (Millipore Sigma). The solution was poured into a release film and doctor bladed to form a thin coating. The film was placed in an oven and the temperature was slowly ramped up to 120° C. over 1 hour to dry the film. The dried film was not rollable, as it was too brittle. The film was cured at 250° C. for 1 hour in an oven to produce a very hard, yet flexible film.

Additional properties of Compound 1 are summarized below in Table 2.

TABLE 2
Properties of Compound 1 Film:

| Property | Value |
|---|---|
| Glass Transition Temperature (T_{g}) (TMA) | 214° C. |
| Coefficient of Thermal Expansion (CTE) of | 31 ppm |
| (TMA) | |
| Dielectric Constant (Dk) | 2.69 @20 GHz |
| Loss Tangent (Df) | 0.008@20 GHz |
| UL94 Flammability Rating | V-0 |

### Example 2: Synthesis of Maleimide-Terminated High MW Polyimide, Compound 2

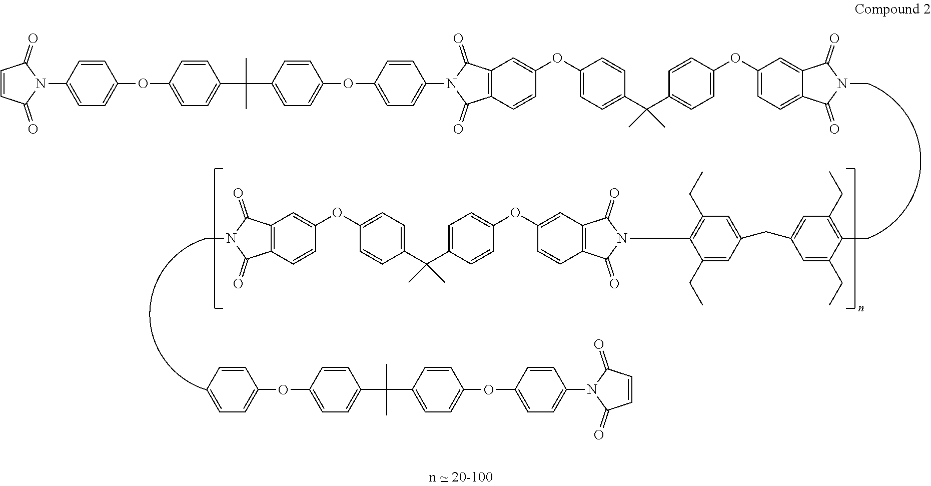

A 3 L reactor was charged with 0.90 mol (279.3 g) of 4,4′-methylenebis(2,6-diethylaniline) along with 1500 g of anisole (Kessler Chemicals; Charlotte N.C.). The solution was stirred while 1.0 mol (520.5 g) of bisphenol-A-dianhydride (Millipore Sigma) was added to the reactor. The mixture was stirred to form a dark purple solution, followed by heating to about 155° C. to obtain reflux, during which the water produced during the imidization reaction was collected in a Dean-Stark trap. After approximately 2 hours the reaction was complete, thereby producing an anhydride-terminated polyimide as no further water was generated in the reaction. The solution was cooled to under 100° C., and quickly 0.15 mol (61.6 g) 2,2-bis[4-(4-aminophenoxy) phenyl] propane (Wilshire Technologies; Princeton N.J.) was added to the reactor. The solution was heated to reflux for another 1 hour and the water was removed to produce an amine-terminated polyimide. The solution was cooled to room temperature, followed by the addition of 0.12 mol (11.8 g; 20% excess) maleic anhydride (Millipore Sigma), followed by the addition of 10.0° g of Amberlyst® 36 acidic ion exchange resin. The mixture was again heated to reflux for 1 hour to produce a maleimide-terminated polyimide. The solution was cooled down to room temperature and the Amberlyst® 36 resin beads were filtered out using a polyester fabric. Excess anisole was removed under reduced pressure to provide a 25% solids solution and the polyimide product stored as a solution in anisole, with 100% yield.

Characterization of Product: ¹H NMR (CDCl₃) δ 1.11 (t, 6H), 1.74 (s, 3H), 2.43 (q, 4H), 3.81 (s, 1H), 4.03 (s, 1H), 7.05 (d, 2H), 7.07 (s, 2H), 7.35 (d, 2H), 7.39 (dd, 1H), 7.43 (d, 1H), 7.91 (d, 1H). FTIR vₘₐₓ 2962, 1721, 1600, 1495, 1362, 1238, 1037, 720, 689.

Molecular Weight. Permeation Chromatography (GPC) analysis showed an average molecular weight (MW) of ˜65,000 Daltons with a Polydispersity Index (PDI) index of 1.2.

Film Preparation. To a solution of the material was added 2% dicumyl peroxide based on the weight of the polyimide. The solution was doctor bladed into a thin film, which was dried in the oven by heating to 120° C. to evaporate the anisole solvent. The dried film had excellent flexibility and was capable of being rolled. The dried film was placed back in the oven and slowly the temperature was raised to 250° C. to cure the film. Once cured, the film remained very flexible.

Copper Laminate. The solution above was also Doctor bladed onto thin copper sheets (25-30 μm thickness) and dried at 120° C. for 30 minutes. The B-staged adhesive film was sandwiched between two sheets of copper film and placed in a laminating press for 1 hour at 200° C. to cure the resin. The copper laminate was cooled to room temperature and was found to be very flexible as it could be bend 180° with no damage. The peel strength was determined to be about 1 N/mm as tested on an Instron peel tester.

Additional properties of Compound 2 are summarized below in Table 3.

TABLE 3
Properties of Compound 2 Film

| Property | Value |
|---|---|
| Glass Transition Temperature (T_{g}) (TMA) | 204° C. |
| Coefficient of Thermal Expansion (CTE) (TMA) | 30 ppm |
| Dielectric Constant (Dk) | 2.9 @20 GHz |
| Loss Tangent (Df) | 0.0073@20 GHz |
| UL94 Flammability Rating | V-0 |

### Example 3: Synthesis of Benzoxazine Terminated High MW Polyimide (Compound 3)

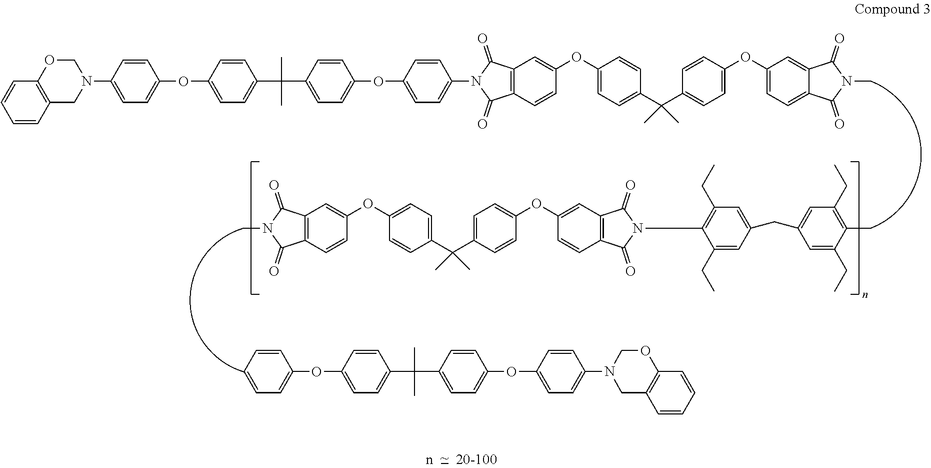

A 3 L reactor was charged with 0.90 mol (279.3 g) of 4,4′-methylenebis(2,6-diethylaniline) (Millipore Sigma) and 1500 g of anisole (Kessler Chemicals). The solution was stirred while a mixture of 1.0 mol (520.5 g) bisphenol-A-dianhydride (Millipore Sigma) was added to the reactor. The mixture was stirred to form a dark purple solution, followed by heating to about 155° C. to obtain reflux, during which the water produced during the imidization reaction was collected in a Dean-Stark trap. After approximately 2 hours the reaction was complete thereby producing an anhydride-terminated polyimide as no further water was generated in the reaction. The solution is cooled to under 100° C., and quickly 0.15 mol (61.6 g) 2,2-bis[4-(4-aminophenoxy) phenyl] propane (Wilshire Technologies, Princeton N.J.) was added to the reactor. The solution was heated to reflux for another 1 hour and the water was removed to produce an amine-terminated polyimide. The solution was cooled to room temperature, followed by the addition of 0.12 mol (11.3 g; 20% excess) phenol (TCI America; Portland Oreg.), followed by the addition of 0.24 mol (7.2 g) paraformaldehyde (TCI America). The solution was again heated to reflux for 1 hour to produce a benzoxazine-terminated polyimide. Excess anisole was removed under reduced pressure to provide a 25% solids solution with 100% yield of product.

Characterization of Product: ¹H NMR (CDCl₃) δ 1.11 (t, 6H), 1.76 (s, 3H), 2.43 (q, 4H), 4.63 (s, faint benzoxazine), 5.33 (s, faint benzoxazine), 7.05 (d, 2H), 7.09 (s, 2H), 7.35 (m, 3H), 7.38 (dd, 1H), 7.43 (d, 1H), 7.89 (d, 1H). FTIR vₘₐₓ 2962, 1719, 1605, 1496, 1362, 1237, 1038, 742, 692.

Film Preparation. The material was processed as described above, to prepare a film. The dried film was very flexible and rollable. The film was then cured in an oven at 250° C. for 1 hour.

Molecular Weight. Permeation Chromatography (GPC) analysis showed an average molecular weight (MW) of ˜60,000±5000 Daltons with a Polydispersity Index (PDI) index of 1.2.

Additional properties of Compound 3 are summarized below in Table 4.

TABLE 4
Properties of Compound 3

| Property | Value |
|---|---|
| Glass Transition Temperature (T_{g}) (TMA) | 220° C. |
| Coefficient of Thermal Expansion (CTE) (TMA) | 29 ppm |
| Dielectric Constant (Dk) | 2.8@20 GHz |
| Loss Tangent (Df) | 0.0054@20 GHz |
| UL94 Flammability Rating | V-0 |

### Example 4: Synthesis of Benzoxazine Terminated High MW Polyimide Containing Aliphatic Diamine, Compound 4

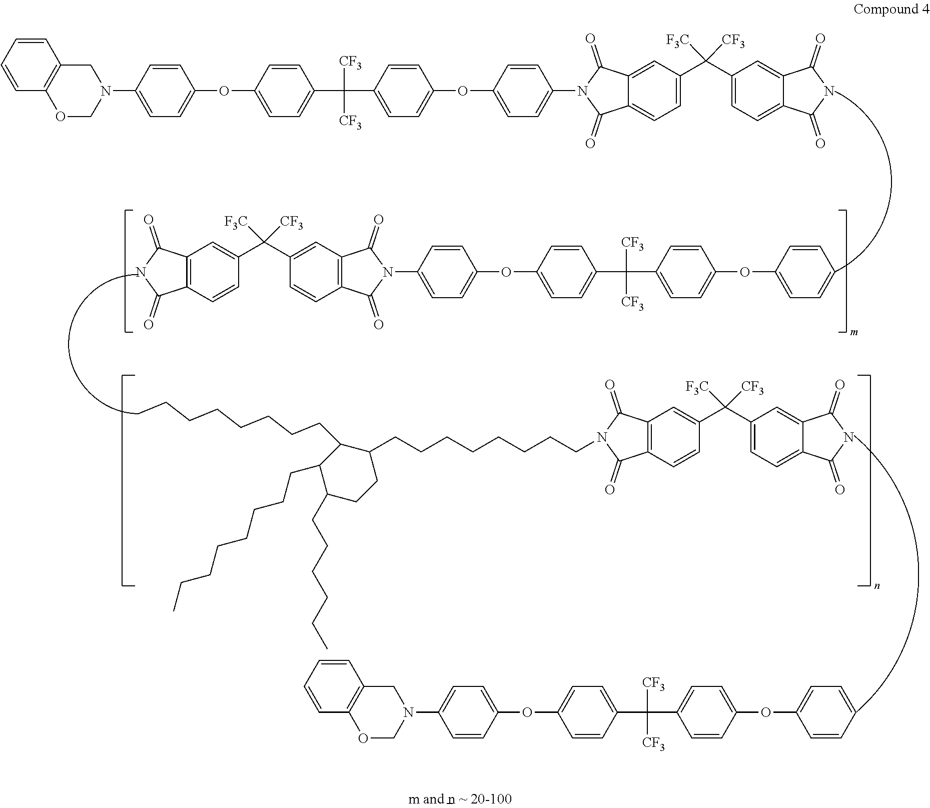

A 1 L round-bottomed flask equipped with a Teflon™-coated stir bar and Dean-Stark trap was charged with 38.8 g (75 mmol) of 2,2-Bis[4-(4-aminophenoxy) phenyl] hexafluoro propane (Wilshire Technologies); 16.5 g (30 mmol)) PRIAMINE®-1075 (Croda, East Yorkshire, UK; or VERSAMINE®-552, BASF, Ludwigshafen, Germany); and 400 g of anisole (Kessler Chemicals). The solution was stirred and 44.4 g (100 mmol) of 4,4′-(hexafluoroisopropylidene) diphthalic anhydride (Wilshire Technologies) was added to the flask. The mixture was stirred and slowly heated to 130° C. to dissolve all the solids and form a polyamic acid. The solution was then heated to reflux for 1 hour to completely remove water and form an amine-terminated polyimide. The light-yellow colored solution was cooled to room temperature followed by the addition of 0.75 g of paraformaldehyde (TCI America), 0.98 g (10.4 mmol) of phenol (TCI America) and 100 g of toluene (Gallade Chemicals). The solution was heated again to reflux for about 1 hour to complete benzoxazine formation with the azeotropic removal of water, excess formaldehyde and phenol. The toluene was also removed by rotary evaporation, and the material concentrated to 25% solids in anisole with 100% yield of product.

Characterization of Product: ¹H NMR (CDCl₃) δ 0.88 (s, 2H), 1.26 (m, 10H), 1.34 (s, 2H), 4.63 (s, faint benzoxazine), 5.33 (s, faint benzoxazine), 7.06 (d, 2H), 7.20 (d, 2H), 7.44 (m, 4H), 7.79 (m, 1H), 7.89 (m, 1H), 7.95 (m, 1H), 8.06 (t, 1H). ¹³C NMR (CDCl₃) δ 14.3, 22.9, 27.0, 28.7, 29.9, 32.1, 38.7, 118.5, 120.1, 123.7, 124.9, 125.6, 128.5, 133.3, 136.1, 139.5, 156.4, 157.5, 166.1, 166.3. FTIR: vₘₐₓ 1717, 1502, 1374, 1240, 1171, 1109, 828, 720, 511.

Molecular Weight. Permeation Chromatography (GPC) analysis showed an average molecular weight (MW) of ˜˜70,000±10,000 Daltons with a Polydispersity Index (PDI) index of 1.2.

Film Preparation. The material was processed as described above, to prepare a film. The film was then cured in an oven at 250° C. for 1 hour.

Additional properties of Compound 4 are summarized below in Table 6.

TABLE 5
Properties of Compound 4

| Property | Value |
|---|---|
| CTE | 69 ppm/° C. |
| T_{g} (DMA) | 176° C. |
| Modulus @25° C. | 920 MPa |
| Dk@20 GHz | 2.55 |
| Df@20 GHz | 0.00158 |
| Td (5%), Air | 412° C. |
| Flammability UL 94 | Flammable* |

### Example 5: Synthesis of Benzoxazine Terminated High MW Polyimide Containing Less Aliphatic Diamine, Compound 5

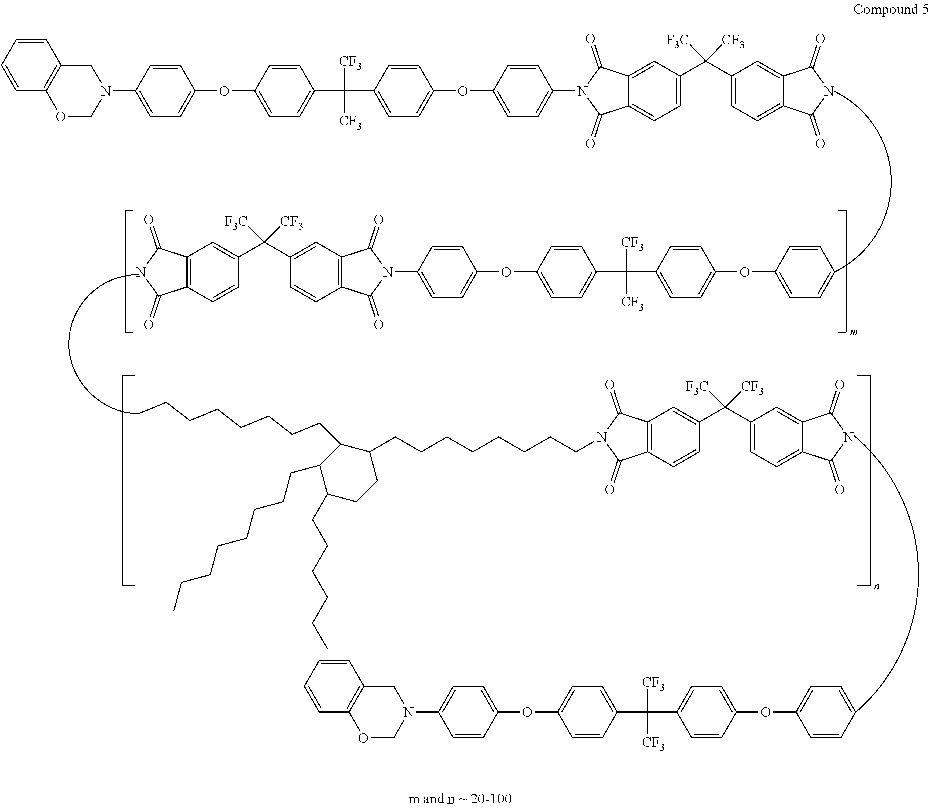

A 1 L round-bottomed flask equipped with a Teflon™-coated stir bar and Dean-Stark trap was charged with 44.1 (85 mmol) of 2,2-Bis[4-(4-aminophenoxy) phenyl] hexafluoro propane (Wildshire Technologies, Princeton N.J.), 11.0 g (20 mmol) PRIAMINE®-1075 (Croda, East Yorkshire, UK; or VERSAMINE®-552, BASF, Ludwigshafen, Germany) and 400 g anisole. The solution was stirred and 44.4 g (100 mmol) of 4,4′-(hexafluoroisopropylidene)diphthalic anhydride (Wilshire Technologies, Princeton N.J.) was added to the flask. The mixture was stirred and slowly heated to 130° C. dissolve all the solids to form a polyamic acid. The solution was then heated to reflux for 1 hour to completely remove water and form an amine-terminated polyimide. The light-yellow colored solution was cooled down to room temperature followed by the addition of 0.75 g of paraformaldehyde, 0.98 g (10.4 mmol) of phenol, and 100 g of toluene. The solution was heated again to reflux for about 1 hour to complete benzoxazine formation with the azeotropic removal of water, molar excess formaldehyde and phenol. The toluene was also removed by rotary evaporation, and the material concentrated to 25% solids in anisole, with 100% yield of product.

Characterization of Product: ¹H NMR (CDCl₃) δ 0.88 (s, 2H), 1.26 (m, 10H), 1.34 (s, 2H), 4.63 (s, faint benzoxazine), 5.33 (s, faint benzoxazine), 7.06 (d, 2H), 7.20 (d, 2H), 7.44 (m, 4H), 7.79 (m, 1H), 7.89 (m, 1H), 7.95 (m, 1H), 8.06 (t, 1H). ¹³C NMR ((CDCl₃) δ 14.3, 22.9, 27.0, 28.7, 29.9, 32.1, 38.7, 118.5, 120.1, 123.7, 124.9, 125.6, 128.5, 133.3, 136.1, 139.5, 156.4, 157.5, 166.1, 166.3. FTIR: vₘₐₓ 1717, 1502, 1374, 1240, 1171, 1109, 828, 720, 511

Additional properties of Compound 5 are summarized below in Table 6.

TABLE 6
Properties of Compound 5

| Property | Value |
|---|---|
| CTE | 46 ppm/° C. |
| T_{g} (DMA) | 196° C. |
| Modulus @25° C. | 1.65 GPa |
| Dk@20 GHz | 2.5 |
| Df@20 GHz | 0.0021 |
| Td (5%), Air | 443° C. |
| Flammability UL 94 | Flammable* |

### Example 6: Synthesis of Maleimide Terminated High MW Polyimide, Compound 6

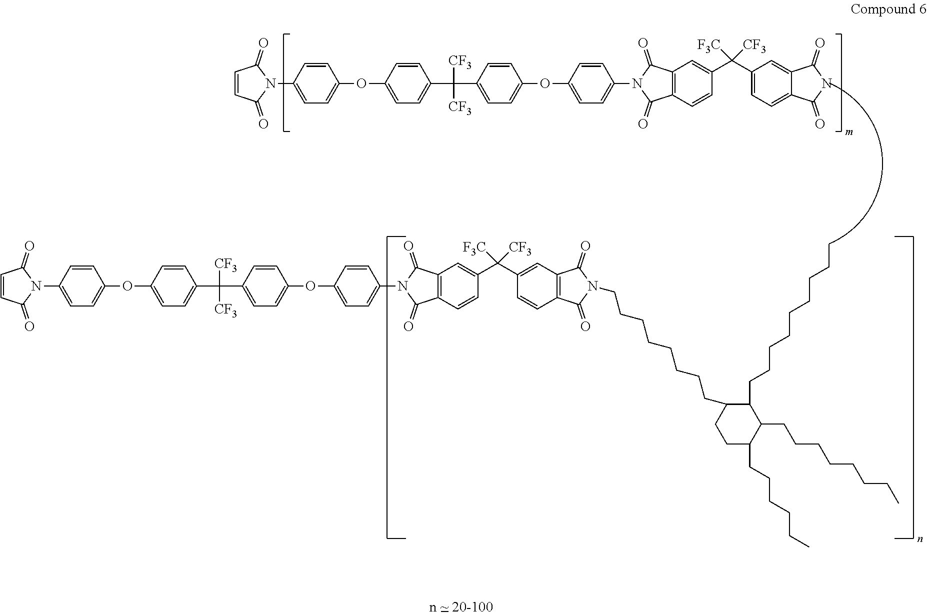

A 2 L round-bottomed flask equipped with a Teflon™-coated stir bar and Dean-Stark trap was charged with 77.7 (150 mmol) of 2,2-Bis[4-(4-aminophenoxy) phenyl] hexafluoro propane (Wilshire Technologies); 11.0 g (60 mmol) PRIAMINE®-1075 (Croda, East Yorkshire, UK; or VERSAMINE®-552, BASF, Ludwigshafen, Germany); and 800 g anisole. The solution was stirred and 88.9 g (200 mmol) of 4,4′-(hexafluoroisopropylidene)diphthalic anhydride (Wilshire Technologies) was added to the flask. The mixture was stirred and slowly heated to 130° C. dissolve all the solids to form a polyamic acid. The solution was then heated to reflux for 1 hour to completely remove water and form an amine-terminated polyimide. The light-yellow colored solution was cooled down to room temperature followed by the addition of 2.45 g (25 mmol) of maleic anhydride, 10 g Amberlyst-36 acidic ion exchange resin. The solution was heated again to reflux for about 2 hours to complete formation of the maleimide. The excess anisole was removed by rotary evaporator the material concentrated to 20% solids in anisole, with 100/0 yield of product.

Characterization of Product: ¹H NMR (CDCl₃) δ δ 0.88 (s, 2H), 1.26 (m, 10H), 1.34 (s, 2H), 3.81 (s, 1H), 4.03 (s, 1H), 7.06 (d, 2H), 7.20 (d, 2H), 7.44 (m, 4H), 7.79 (m, 1H), 7.89 (m, 1H), 7.95 (m, 1H), 8.06 (t, 1H). ¹³C NMR ((CDCl₃) δ 14.3, 22.9, 27.0, 28.7, 29.9, 32.1, 38.7, 118.5, 120.1, 123.7, 124.9, 125.6, 128.5, 133.3, 136.1, 139.5, 156.4, 157.5, 166.1, 166.3. FTIR: vₘₐₓ 1717, 1502, 1374, 1240, 1171, 1109, 828, 720, 698, 511

Molecular Weight. The average MW was determined to be about 69,000 Daltons with a polydispersity index of 1.2.

Film Preparation. The material was processed as described above, to prepare a film. The material was cured in an oven at 250° C. for 1 hour to form a flexible rollable film.

The properties of Compound 6 are summarized below in Table 7.

TABLE 7
Properties of Compound 6

| Property | Value |
|---|---|
| CTE | 58 ppm/° C. |
| T_{g} (DMA) | 162° C. |
| Modulus @25° C. | 1.65 GPa |
| Dk@20 GHz | 2.405 |
| Df@20 GHz | 0.0018 |
| Td (5%), Air | 443° C. |
| Flammability UL 94 | Flammable* |

### Example 7: Comparison of Resins

The fully aromatic polyimides (examples 1-3) have been shown to have the highest T_{g} and lowest CTE of the examples shown. Unfortunately, the dissipation factor of these materials is not as good, all having a Df value above 0.005. By adding a small amount of aliphatic diamine (Priamine®-1075) we were able to increase the MW slightly, increase the flexibility, as well as decreasing the Df values @ 20 GHz to about 0.002 which is a desired value for high frequency applications, the direct comparison can be found in Table 8.

TABLE 8
Comparison of Polyimide Properties

| | Compounds | | | | |
|---|---|---|---|---|---|
| Property | 1 | 2 | 3 | 4 | 5 |
| Molecular weight | 22,500 | 60,000 +/− 10,000 | 60,000 +/− 5000 | 70,000 +/− 10,000 | 85,000 +/− 10,000 |
| CTE by TMA, | 31 | 30 | 29 | 69/104 | 46/251 |
| (ppm/° C.) | | | | | |
| Tg by TMA, (° C.) | 214 | 204 | 220 | 176.3 | 196.41 |
| Dk @20 GHz | 2.65 | 2.9 | 2.8 | 2.55 | 2.5 |
| Df @20 GHz | 0.008 | 0.0073 | 0.0054 | 0.00158 | 0.00210 |

### Example 8: Comparative Examples

A series of maleimide terminated polyimides were synthesized with varying diamine to dianhydride ratios for the purposes of evaluating the average MW obtained versus the current invention. All reactions were conducted in a 1 L reaction vessel in a solution of 200 g of toluene (Gallade Chemicals) and 300 g of N-methylpyrollidone (NMP) (Gallade Chemicals) with the addition of 15 g of methanesulfonic acid (MSA) (Millipore Sigma) as the catalyst. The diamine was added to the solution above, followed by the addition of the dianhydride. The solution was refluxed for 2 hours at 110° C. to remove the water from the condensation reaction. The solution is cooled down to room temperature, followed by the addition of 1.2 equivalents of maleic anhydride (Millipore Sigma). The solution is refluxed again at 110° C. for 6-8 hours to complete the formation of the maleimide terminated polyimide. The solution was then washed three times with 300 g of a 90/10 solution of water and ethanol to remove the NMP and MSA. The organic layer was then added dropwise to a stirred container of methanol to precipitate the product. The solid precipitate was filtered and dried in a oven at 50° C. for several hours to provide the dried maleimide-terminated polyimide powder. The powder was analyzed using GPC to obtain the average MW data, which is shown in Table 9.

### Reagents:

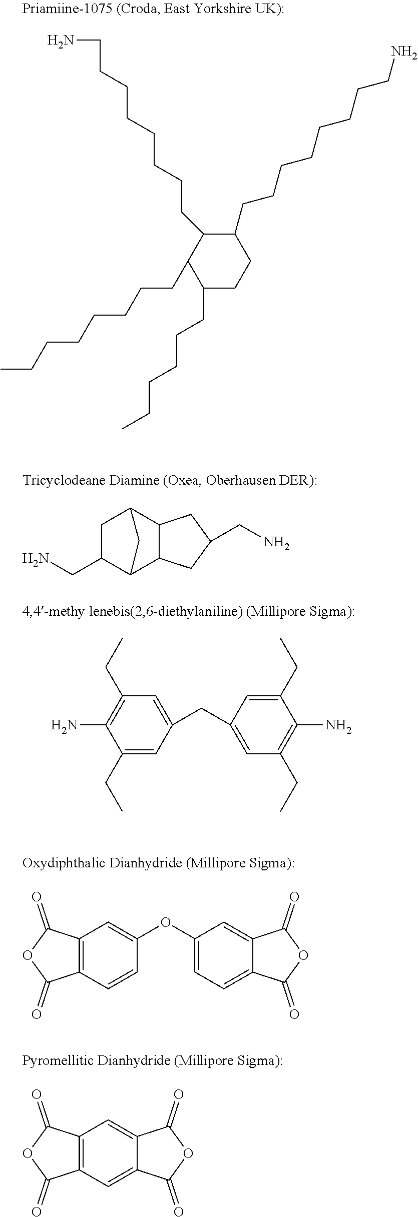 [SMILES: CCCCCCCCC1C(CCCCCC)CCC(CCCCCCCCN)C1CCCCCCCCN ; NCC1CC2C3CC(CN)C(C3)C2C1 ; CCc1cc(Cc2cc(CC)c(N)c(CC)c2)cc(CC)c1N ; O=C1OC(=O)c2cc(Oc3ccc4c(c3)C(=O)OC4=O)ccc21 ; O=c1oc(=O)c2cc3c(=O)oc(=O)c3cc12]

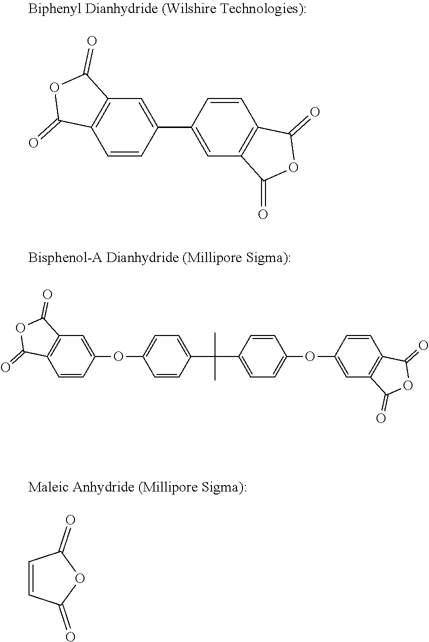 [SMILES: O=C1OC(=O)c2cc(-c3ccc4c(c3)C(=O)OC4=O)ccc21 ; CC(C)(c1ccc(Oc2ccc3c(c2)C(=O)OC3=O)cc1)c1ccc(Oc2ccc3c(c2)C(=O)OC3=O)cc1 ; O=C1C=CC(=O)O1]

TABLE 9
MW of Maleimide Terminated Polyimide based
on Ratio of Daimine/Dianhydride

| | | | Ratio | Average |
|---|---|---|---|---|
| Example | Diamine | Dianhydride | Diamine: | MW |
| # | Equivalents | Equivalents | Dianhydride | (Daltons) |
| 1 | 2 Eq Priamine- | 1 Eq | 2.0/1 | 1,500 |
| | 1075 | Oxydiphthalic | | |
| | | Dianhydride | | |
| 2 | 1.5 Eq Priamine- | 1 Eq Pyromellitic | 1.5/1 | 3,000 |
| | 1075 | Dianhydride | | |
| 3 | 1.06 Eq TCD- | 1 Eq Biphenyl | 1.33/1 | 5,500 |
| | Diamine | Dianhydride | | |
| | 0.27 Eq Priamine- | | | |
| | 1075 | | | |
| 4 | 0.96 Eq 4,4′- | 0.6 Eq Biphenyl | 1.2/1 | 13,500 |
| | methylenebis(2,6- | Dianhydride | | |
| | diethylaniline) | 0.4 Eq Bisphenol- | | |
| | 0.24 Eq Priamine- | A Dianhydride | | |
| | 1075 | | | |
| 5 | 0.55 Eq TCD- | 1 Eq Biphenyl | 1.1/1 | 21,000 |
| | Diamine | Dianhydride | | |
| | 0.55 Eq Priamine- | | | |
| | 1075 | | | |

Table 9 demonstrates that a diamine to dianhydride ratio of about 1.1/1 is required to obtain functionalized polyimides that have average MW greater than 20,000 Daltons. The low MW materials with high functionality are appropriate for certain applications, however, to make very flexible films, high MW is desirable. All of the examples have a ratio of diamine to dianhydride of 1.05/1 and produce very high MW flexible polymeric films.

1-54. (canceled)

55. A high molecular weight, curable polyimide compound having a structure according to the following Formula I: 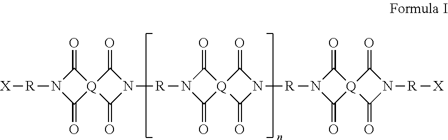
wherein,
R is selected from the group consisting of: substituted or unsubstituted aromatic, aliphatic, cycloaliphatic, alkenyl, polyether, polyester, polyamide, heteroaromatic, and siloxane, and combinations thereof;
Q is selected from the group consisting of: substituted or unsubstituted aromatic, aliphatic, cycloaliphatic, alkenyl, polyether, polyester, polyamide, heteroaromatic, siloxane, and combinations thereof;
X is a curable moiety, optionally selected from the group consisting of: maleimide, benzoxazine, citraconimide, itaconimide, methacrylamide, acrylamide, phenolic, free-amine, carboxylic acid, alcohol, acrylate, methacrylate, oxazoline, vinyl ether, vinyl ester, allylic, vinylic, anhydride, and combinations thereof; and
n is 0 or an integer having the value from 1 to 100 or an integer having the value from 20-100; and with the proviso that, the average molecular weight of the material is greater than 20,000 Daltons or is 25,000 to 50,000 Daltons.

56. A method for synthesizing the high molecular weight, curable polyimide compound of claim 55 comprising the steps of:
a. providing at least one diamine and at least one dianhydride;
b. combining the at least one diamine with the at least one dianhydride in a solvent to form a mixture;
c. refluxing the mixture, thereby forming a polyamic acid in the solution;
d. azeotropically distilling the polyamic acid in the solution, thereby forming an amine-terminated polyimide in the solution; and
e. functionalizing the amine-terminated polyimide by reacting the terminal amine groups to form curable terminal moieties on the polyimide, wherein the curable polyimide has a molecular weight greater than 20,000 Dalton;
thereby synthesizing the high molecular weight, curable polyimide compound.

57. The method of claim 56, wherein:
i. the at least one diamine, the at least one dianhydride or both are soluble in the solvent; or
ii. the high molecular weight, curable polyimide is soluble in the solvent; or
iii. the polyamic acid of step c is soluble in the solvent; or
iv. the amine-terminated polyimide of step d is soluble in the solvent; or
v. any combination of i.-iv.; and
wherein the solvent is optionally anisole.

58. The method of claim 56, wherein the at least one diamine is provided in excess of the at least one dianhydride, optionally wherein the equivalent ratio of the at least one diamine to the at least one dianhydride is about 1.01:1 to about 1.10:1 or is about 1.02:1 to about 1.09:1; about 1.03:1 to about 1.08:1; about 1.04:1 to about 1.07:1; or about 1.05:1 to about 1.06; or is about 1.05:1.

59. The method of claim 56, wherein the at least one diamine is selected from the group consisting of: 1,10-diaminodecane; 1,12-diaminododecane; dimer diamine; hydrogenated dimer diamine; 1,2-diamino-2-methylpropane; 1,2-diaminocyclohexane; 1,2-diaminopropane; 1,3-diaminopropane; 1,4-diaminobutane; 1,5-diaminopentane; 1,7-diaminoheptane; 1,8-diaminomethane; 1,8-diaminooctane; 1,9-diaminononane; 3,3′-diamino-N-methyldipropylamine; diaminomaleonitrile; 1,3-diaminopentane; 9,10-diaminophenanthrene; 4,4′-diaminooctafluorobiphenyl; 3,5-diaminobenzoic acid; 3,7-diamino-2-methoxyfluorene; 4,4′-diaminobenzophenone; 3,4-diaminobenzophenone; 3,4-diaminotoluene; 2,6-diaminoanthroquinone; 2,6-diaminotoluene; 2,3-diaminotoluene; 1,8-diaminonaphthalene; 2,4-diaminotoluene; 2,5-diaminotoluene; 1,4-diaminoanthroquinone; 1,5-diaminoanthroquinone; 1,5-diaminonaphthalene; 1,2-diaminoanthroquinone; 2,4-cumenediamine; 1,3-bisaminomethylbenzene; 1,3-bisaminomethylcyclohexane; 2-chloro-1,4-diaminobenzene; 1,4-diamino-2,5-dichlorobenzene; 1,4-diamino-2,5-dimethylbenzene; 4,4′-diamino-2,2′-bistrifluoromethylbiphenyl; bis(amino-3-chlorophenyl)ethane; bis(4-amino-3,5-dimethylphenyl)methane; bis(4-amino-3,5-diethylphenyl)methane; bis(4-amino-2-chloro-3,5-diethylphenyl)methane; bis(4-amino-3,5-diisopropylphenyl)methane; bis(4-amino-3,5-methylisopropylphenyl)methane; bis(4-amino-3,5-bis(4-amino-3-ethylphenyl)methane; diaminofluorene; 4,4′-(9-Fluorenylidene)dianiline; diaminobenzoic acid; 2,3-diaminonaphthalene; 2,3-diaminophenol; bis(4-amino-3,5-dimethylphenyl)methane; bis(4-amino-3-methylphenyl)methane; bis(4-amino-3-ethylphenyl)methane; 4,4′-diaminophenylsulfone; 3,3′-diaminophenylsulfone; 2,2-bis(4-(4-aminophenoxy)phenyl)sulfone; 2,2-bis(4-(3-aminophenoxy)phenyl)sulfone; 4,4′-oxydianiline; 4,4′-diaminodiphenyl sulfide; 3,4′-oxydianiline; 2,2-bis(4-(4-aminophenoxy)phenyl)propane; 1,3-bis(4-aminophenoxy)benzene; 4,4′-bis(4-aminophenoxy)biphenyl; 4,4′-diamino-3,3′-dihydroxybiphenyl; 4,4′-diamino-3,3′-dimethylbiphenyl; 4,4′-diamino-3,3′-dimethoxybiphenyl; Bisaniline M; Bisaniline P; 9,9-bis(4-aminophenyl)fluorene; o-tolidine sulfone; methylene bis(anthranilic acid); 1,3-bis(4-aminophenoxy)-2,2-dimethylpropane; 1,3-bis(4-aminophenoxy)propane; 1,4-bis(4-aminophenoxy)butane; 1,5-bis(4-aminophenoxy)butane; 2,3,5,6-tetramethyl-1,4-phenylenediamine; 3,3′,5,5′-tetramehylbenzidine; 4,4′-diaminobenzanilide; 2,2-bis(4-aminophenyl)hexafluoropropane; polyoxyalkylenediamines; 1,3-cyclohexanebis(methylamine); m-xylylenediamine; p-xylylenediamine; bis(4-amino-3-methylcyclohexyl)methane; 1,2-bis(2-aminoethoxy)ethane; 3(4),8(9)-bis(aminomethyl)tricyclo(5.2.1.0^{2,6})decane and combinations thereof.

60. The method of claim 56, wherein the at least one dianhydride is selected from the group consisting of: polybutadiene-graft-maleic anhydride; polyethylene-graft-maleic anhydride; polyethylene-alt-maleic anhydride; polymaleic anhydride-alt-1-octadecene; polypropylene-graft-maleic anhydride; poly(styrene-co-maleic anhydride); pyromellitic dianhydride; maleic anhydride, succinic anhydride; 1,2,3,4-cyclobutanetetracarboxylic dianhydride; 1,4,5,8-naphthalenetetracarboxylic dianhydride; 3,4,9,10-perylenentetracarboxylic dianhydride; bicyclo(2.2.2)oct-7-ene-2,3,5,6-tetracarboxylic dianhydride; diethylenetriaminepentaacetic dianhydride; ethylenediaminetetraacetic dianhydride; 3,3′,4,4′-benzophenone tetracarboxylic dianhydride; 3,3′,4,4′-biphenyl tetracarboxylic dianhydride; 4,4′-oxydiphthalix anhydride; 3,3′,4,4′-diphenylsulfone tetracarboxylic dianhydride; 2,2′-bis(3,4-dicarboxyphenyl)hexafluoropropane dianhydride; 4,4′-bisphenol A diphthalic anhydride; 5-(2,5-dioxytetrahydro)-3-methyl-3-cyclohexene-1,2-dicarboxylic anhydride; ethylene glycol bis(trimelitic anhydride); hydroquinone diphthalic anhydride; allyl nadic anhydride; 2-octen-1-ylsuccinic anhydride; phthalic anhydride; 1,2,3,6-tetrahydrophthalic anhydride; 3,4,5,6-tetrahydrophthalic anhydride; 1,8-naphthalic anhydride; glutaric anhydride; dodecenylsuccinic anhydride; hexadecenylsuccinic anhydride; hexahydrophthalic anhydride; methylhexahydrophthalic anhydride; tetradecenylsuccinic anhydride; trimellitic anhydride; and combinations thereof.

61. The method of claim 56, wherein functionalizing the amine-terminated polyimide comprises:
a. reacting the terminal amine groups with an anhydride, wherein optionally, the anhydride is maleic anhydride and the terminal amine groups are converted to maleimides groups; or
b. reacting the terminal amine groups with a phenolic moiety and formaldehyde, wherein terminal amine groups are converted to benzoxazine groups.

62. A high molecular weight, curable polyimide, synthesized by the method of claim 56.

63. A high molecular weight, curable polyimide compound according to claim 55, wherein the compound has a dielectric constant less than 3.0 and a dielectric dissipation factor less than 0.005.

64. A composition comprising a high molecular weight, curable polyimide compound according to claim 55,
wherein the composition comprises at least one filler, coupling agent, co-curable reactive resin, coupling agent, adhesion promoter, catalyst or fire retardant; and
wherein the filler is optionally silica or perfluorotetraethylene or is a combination of perfluorotetraethylene and silica, or is selected from the group consisting of boron nitride, alumina, carbon black, graphite, carbon nanotubes, polyhedral oligomeric silsesquioxane (POSS), silver, copper and metal alloys; or
wherein the co-curable reactive resin is optionally selected from the group consisting of: an epoxy resin, a cyanate ester resin, a benzoxazine resin, a bismaleimide resin, a phenolic resin, a carboxyl resin, a liquid crystal polymer resin, a reactive ester resins, an acrylic resin and a tackifier.

65. A method for preparing a prepreg comprising the steps of:
a. providing a reinforcing fiber, wherein the reinforcing fiber is optionally a woven or unwoven fabric;
b. immersing the reinforcing fiber in a liquid formulation of an uncured composition comprising a high molecular weight, curable polyimide compound of claim 55, thereby impregnating the reinforcing fiber;
c. optionally, draining the prepreg to remove excess liquid formulation; and
d. optionally, drying the prepreg.
thereby preparing a prepreg.

66. A prepreg prepared according to the method of claim 65.

67. A method for preparing a copper-clad laminate (CCL) comprising the steps of:
a. providing the prepreg of claim 66, and
b. disposing copper on one or both sides of the prepreg,
wherein disposing optionally consists of electroplating copper to the one or the both sides of the prepreg or laminating copper foil to the one or the both sides of the prepreg;
thereby preparing a copper-clad laminate.

68. A CCL prepared according to the method of claim 67.

69. A method for preparing a printed circuit board (PCB) comprising the steps of:
a. providing the CCL of claim 68;
b. etching circuit traces in the copper disposed on the one or the both sides of the CCL,
thereby preparing a printed circuit board.

70. A method for preparing a flexible copper clad laminate (FCCL) comprising the steps of:
a. providing a film comprising a high molecular weight, curable polyimide compound according to claim 55, wherein the film is optionally an adhesive film;
b. applying an adhesive to one of both sides of the film;
c. laminating copper foil to the adhesive on the one or the both sides of the film,
thereby preparing a FCCL.

71. A method for preparing a flexible copper clad laminate (FCCL) comprising the steps of:
a. providing a film comprising a high molecular weight, curable polyimide compound according to claim 55, wherein the film is an adhesive film;
b. optionally applying an adhesive to one of both sides of the film;
c. laminating copper foil to the adhesive on the one or the both sides of the film,
thereby preparing a FCCL.

72. An FCCL comprising a film formulation of the composition of claim 64, having copper foil laminated to one or both sides of the film, optionally comprising an adhesive layer between each copper foil and the film.

73. An FCCL prepared according to the method of claim 70.

74. A method for preparing a thin, flexible electronic circuit, comprising the steps of
a. providing the FCCL of claim 73; and
b. etching circuit traces in the copper foil on one or both sides of the FCCL;
thereby preparing a thin, flexible circuit.
